(19) United States
(12) Patent Application Publication
(10) Pub. No.: US 2026/0322355 A1
(43) Pub. Date: Oct. 15, 2026

(54) ACOUSTIC WAVE DEVICE AND FILTER DEVICE

(71) Applicant: Murata Manufacturing Co., Ltd., Nagaokakyo-shi (JP)

(72) Inventors: Kentaro NAKAMURA, Nagaokakyo-shi (JP); Takuya YABU, Nagaokakyo-shi (JP)

(21) Appl. No.: 19/464,836

(22) Filed: Jan. 30, 2026

(30) Foreign Application Priority Data
Feb. 13, 2025 (JP) 2025-021692

(51) Int. Cl. H03H 9/64; H03H 9/00

(52) U.S. Cl. CPC H03H 9/64; H03H 9/0095

(57) ABSTRACT

An acoustic wave device includes a piezoelectric substrate including a piezoelectric layer and an IDT electrode on the piezoelectric layer and including first and second busbars, first and second electrode fingers, and first floating electrodes not connected to the busbars or the electrode fingers. The first electrode fingers include one end portion connected to the first busbar. The second electrode fingers include one end portion connected to the second busbar. A region where the first and second electrode fingers that are adjacent to each other overlap each other in an acoustic wave propagation direction is an intersection region including a central region on a center side in a propagation orthogonal direction, and first and second edge regions. A first mass addition film is provided in the first edge region and a second mass addition film is provided in a first floating electrode formation region.

### CROSS REFERENCE TO RELATED APPLICATIONS

This application claims the benefit of priority to Japanese Patent Application No. 2025-021692 filed on Feb. 13, 2025. The entire contents of this application are hereby incorporated herein by reference.

### BACKGROUND OF THE INVENTION

### 1. Field of the Invention

The present invention relates to acoustic wave devices and filter devices.

### 2. Description of the Related Art

Acoustic wave devices have heretofore been widely used in filters and the like for mobile phones. In acoustic wave devices, various unwanted waves are generated, other than a main mode used to form a band of a filter. For example, a transverse mode occurs at frequencies between a resonant frequency and an anti-resonant frequency of the main mode. To obtain a good response of the main mode, it is important to reduce the response of unwanted waves, such as the transverse mode.

Japanese Unexamined Patent Application Publication No. 2018-174595 discloses an example of an acoustic wave device. In this acoustic wave device, a high acoustic velocity member, a low acoustic velocity film, and a piezoelectric film are stacked in this order. An interdigital transducer (IDT) electrode is provided on the piezoelectric film.

The IDT electrode includes a pair of busbars and a plurality of electrode fingers. Each busbar includes a plurality of apertures. One end portion of each of the plurality of electrode fingers is connected to one of the pair of busbars. The portions of the plurality of electrode fingers connected to the busbars and their tip end portions include wide portions that are wider than other portions. This configuration can reduce the transverse mode.

However, there is a case where the acoustic wave device described in Japanese Unexamined Patent Application Publication No. 2018-174595 cannot sufficiently reduce leakage of acoustic wave energy from the region where the plurality of electrode fingers are provided to the busbar side.

### SUMMARY OF THE INVENTION

Accordingly, example embodiments of the present invention provide acoustic wave devices each able to reduce or prevent a transverse mode and reduce or prevent leakage of acoustic wave energy.

An acoustic wave device according to an example embodiment of the present invention includes a piezoelectric substrate including a piezoelectric layer, and an IDT electrode on the piezoelectric layer, the IDT electrode including a pair of busbars, a plurality of electrode fingers, and a plurality of first floating electrodes not connected to the pair of busbars or the plurality of electrode fingers. The pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other. A region where the plurality of first electrode fingers and the plurality of second electrode fingers that are adjacent to each other overlap with each other in an acoustic wave propagation direction is denoted as an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side. The plurality of first floating electrodes are located between the first edge region and the first busbar, and a region where the plurality of first floating electrodes are provided is a first floating electrode formation region. The acoustic wave device further includes a first mass addition film in the first edge region, and a second mass addition film in the first floating electrode formation region.

An acoustic wave device according to another example embodiment of the present invention includes a piezoelectric substrate including a piezoelectric layer, and an IDT electrode on the piezoelectric layer, the IDT electrode including a pair of busbars, a plurality of electrode fingers, and a plurality of first floating electrodes not connected to the pair of busbars or the plurality of electrode fingers. The pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other. A region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side. The plurality of first floating electrodes are located between the first edge region and the first busbar, and a region where the plurality of first floating electrodes are provided is a first floating electrode formation region. In the first edge region, at least one of the plurality of first electrode fingers or the plurality of second electrode fingers includes first wide portions wider than a width in the central region. In the first floating electrode formation region, the acoustic wave device has at least one of a configuration in which the plurality of first electrode fingers include second wide portions wider than the width in the central region, or a configuration in which the plurality of first floating electrodes include second wide portions wider than other portions.

An acoustic wave device according to another example embodiment of the present invention includes a piezoelectric substrate including a piezoelectric layer, and an IDT electrode on the piezoelectric layer, the IDT electrode including a pair of busbars, a plurality of electrode fingers, and a plurality of first floating electrodes not connected to the pair of busbars or the plurality of electrode fingers. The pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other. A region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side. The plurality of first floating electrodes are located between the first edge region and the first busbar, and a region where the plurality of first floating electrodes are located is a first floating electrode formation region. The acoustic wave device further includes a first mass addition film in the first edge region. In the first floating electrode formation region, the acoustic wave device includes at least one of a configuration in which the plurality of first electrode fingers include second wide portions wider than a width in the central region, or a configuration in which the plurality of first floating electrodes include second wide portions wider than other portions.

An acoustic wave device according to another example embodiment of the present invention includes a piezoelectric substrate including a piezoelectric layer, and an IDT electrode on the piezoelectric layer, the IDT electrode including a pair of busbars, a plurality of electrode fingers, and a plurality of first floating electrodes not connected to the pair of busbars or the plurality of electrode fingers. The pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other. A region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side. The plurality of first floating electrodes are located between the first edge region and the first busbar, and a region where the plurality of first floating electrodes are located is a first floating electrode formation region. In the first edge region, the plurality of first electrode fingers, the plurality of second electrode fingers, or both include first wide portions wider than a width in the central region. The acoustic wave device further includes a second mass addition film in the first floating electrode formation region.

The acoustic wave devices according to example embodiments of the present invention each reduce or prevent the transverse mode and reduce or prevent the leakage of acoustic wave energy.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic enlarged plan view illustrating the vicinity of an area enclosed by a dash-dot-dot line C in FIG. 1.

FIG. 4 is a schematic enlarged plan view illustrating the vicinity of a first busbar and a second busbar of an IDT electrode in a first comparative example.

FIG. 5 is a graph illustrating impedance-frequency characteristics in the first example embodiment and the first comparative example of the present invention.

FIG. 6 is a graph illustrating return loss in the first example embodiment and the first comparative example of the present invention.

FIG. 7 is a schematic enlarged plan view illustrating the vicinity of a first busbar of an IDT electrode in a second comparative example.

FIG. 8 is a graph illustrating impedance-frequency characteristics in the first example embodiment and the second comparative example of the present invention.

FIG. 9 is a graph illustrating return loss in the first example embodiment and the second comparative example of the present invention.

FIG. 10 is a schematic enlarged plan view illustrating the vicinity of a first busbar of an IDT electrode in a third comparative example.

FIG. 11 is a schematic enlarged plan view illustrating the vicinity of a first busbar of an IDT electrode in a fourth comparative example.

FIG. 12 is a graph illustrating impedance-frequency characteristics in the first example embodiment, the third comparative example, and the fourth comparative example of the present invention.

FIG. 13 is a graph illustrating return loss in the first example embodiment, the third comparative example, and the fourth comparative example of the present invention.

FIG. 14 is a schematic plan view illustrating a circle including an arc when the shape of the electrode fingers of the IDT electrode in plan view in the first example embodiment of the present invention is approximated to an arc.

FIG. 15 is a schematic enlarged plan view illustrating the vicinity of a first busbar of an IDT electrode in a first modification of the first example embodiment of the present invention.

FIG. 16 is a schematic enlarged plan view illustrating the vicinity of a first busbar of an IDT electrode in a second modification of the first example embodiment of the present invention.

FIG. 17 is a schematic enlarged plan view illustrating the vicinity of a first busbar and a second busbar of an IDT electrode in a third modification of the first example embodiment of the present invention.

FIG. 18 is a schematic enlarged plan view illustrating the vicinity of a first busbar and a second busbar of an IDT electrode in a second example embodiment of the present invention.

FIG. 19 is a schematic enlarged plan view illustrating the vicinity of a first busbar and a second busbar of an IDT electrode in a first modification of the second example embodiment of the present invention.

FIG. 20 is a schematic enlarged plan view illustrating the vicinity of a first busbar and a second busbar of an IDT electrode in a second modification of the second example embodiment of the present invention.

FIG. 21 is a schematic enlarged plan view illustrating the vicinity of a first busbar and a second busbar of an IDT electrode in a third modification of the second example embodiment of the present invention.

FIG. 22 is a schematic elevational cross-sectional view illustrating a portion passing through a first edge region of an acoustic wave device according to a third example embodiment of the present invention.

FIG. 23 is a schematic elevational cross-sectional view illustrating a portion passing through a first edge region of an acoustic wave device according to a modification of the third example embodiment of the present invention.

FIG. 24 is a schematic elevational cross-sectional view illustrating a portion passing through a first edge region of an acoustic wave device according to a fourth example embodiment of the present invention.

FIG. 25 is a schematic enlarged plan view illustrating the vicinity of a first busbar and a second busbar of an IDT electrode according to a fifth example embodiment of the present invention.

FIG. 26 is a schematic enlarged plan view illustrating the vicinity of a first busbar and a second busbar of an IDT electrode according to a first modification of the fifth example embodiment of the present invention.

FIG. 27 is a schematic enlarged plan view illustrating the vicinity of a first busbar and a second busbar of an IDT electrode according to a second modification of the fifth example embodiment of the present invention.

FIG. 28 is a schematic plan view of an acoustic wave device according to a sixth example embodiment of the present invention.

FIG. 29 is a schematic enlarged plan view illustrating a plurality of electrode fingers of an IDT electrode in a modification of the sixth example embodiment of the present invention.

FIG. 30 is a schematic enlarged plan view illustrating the vicinity of a first busbar and a second busbar of an IDT electrode in a seventh example embodiment of the present invention.

FIG. 31 is a schematic plan view of an acoustic wave device according to an eighth example embodiment of the present invention.

FIG. 32 is a schematic plan view illustrating parallel regions and non-parallel regions in the eighth example embodiment of the present invention.

FIG. 33 is a schematic elevational cross-sectional view of an acoustic wave device according to a ninth example embodiment of the present invention.

FIG. 34 is a schematic elevational cross-sectional view of an acoustic wave device according to a first modification of the ninth example embodiment of the present invention.

FIG. 35 is a schematic elevational cross-sectional view of an acoustic wave device according to a second modification of the ninth example embodiment of the present invention.

FIG. 36 is a schematic elevational cross-sectional view of an acoustic wave device according to a tenth example embodiment of the present invention.

FIG. 37 is a schematic elevational cross-sectional view of an acoustic wave device according to a first modification of the tenth example embodiment of the present invention.

FIG. 38 is a schematic elevational cross-sectional view of an acoustic wave device according to a second modification of the tenth example embodiment of the present invention.

FIG. 39 is a schematic elevational cross-sectional view of an acoustic wave device according to a third modification of the tenth example embodiment of the present invention.

FIG. 40 is a circuit diagram of a filter device according to an eleventh example embodiment of the present invention.

### DETAILED DESCRIPTION OF THE EXAMPLE EMBODIMENTS

The present invention will be clarified below by describing example embodiments of the present invention with reference to the drawings.

The example embodiments described in this specification are merely examples, and configurations can be partially replaced or combined between different example embodiments.

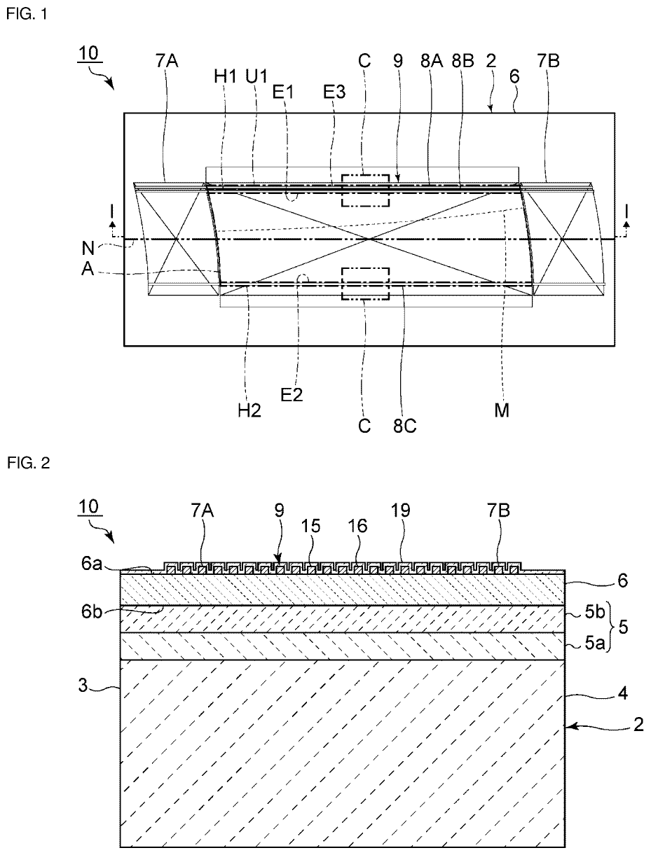

FIG. 1 is a schematic plan view of an acoustic wave device according to a first example embodiment of the present invention. FIG. 2 is a schematic cross-sectional view taken along line I-I in FIG. 1. In FIG. 1, an IDT electrode and each reflector to be described later are illustrated as outlines with two diagonal lines added. A dielectric film to be described later is omitted in FIG. 1.

As illustrated in FIG. 1, an acoustic wave device 10 includes a piezoelectric substrate 2. As illustrated in FIG. 2, the piezoelectric substrate 2 is a multilayer substrate including a piezoelectric layer 6. That is, the piezoelectric substrate 2 is a substrate having piezoelectricity. Specifically, the piezoelectric substrate 2 includes a support 3 and the piezoelectric layer 6. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. However, the layer configuration of the piezoelectric substrate 2 is not limited to the above. For example, the intermediate layer 5 may include a single dielectric layer. Alternatively, the piezoelectric substrate 2 may be a substrate including only the piezoelectric layer 6.

In the present example embodiment, for example, silicon is used as the material of the support substrate 4. Silicon nitride is used as the material of the first layer 5a, for example. Silicon oxide is used as the material of the second layer 5b, for example. Rotated Y-cut X-propagating lithium tantalate is used as the material of the piezoelectric layer 6, for example. As described above, the piezoelectric layer 6 has a propagation axis. The direction in which the propagation axis extends is an X direction. In the present example embodiment, the direction in which the propagation axis extends is parallel or substantially parallel to the direction in which a dash-dot-dot line N in FIG. 1 extends. The materials of the respective layers of the piezoelectric substrate 2 are not limited to those described above.

The piezoelectric layer 6 includes a first main surface 6a and a second main surface 6b. The first main surface 6a and the second main surface 6b face each other. Of the first main surface 6a and the second main surface 6b, the second main surface 6b is located on the support substrate 4 side. An IDT electrode 9 is provided on the first main surface 6a of the piezoelectric layer 6.

A dielectric film 19 is provided on the piezoelectric layer 6 so as to cover the IDT electrode 9. Specifically, the dielectric film 19 is provided on the first main surface 6a of the piezoelectric layer 6. The dielectric film 19 protects the IDT electrode 9, making the IDT electrode 9 less susceptible to damage. In the present example embodiment, for example, silicon oxide is used as the material of the dielectric film 19. However, the material of the dielectric film 19 is not limited to the above. The dielectric film 19 does not necessarily have to be provided.

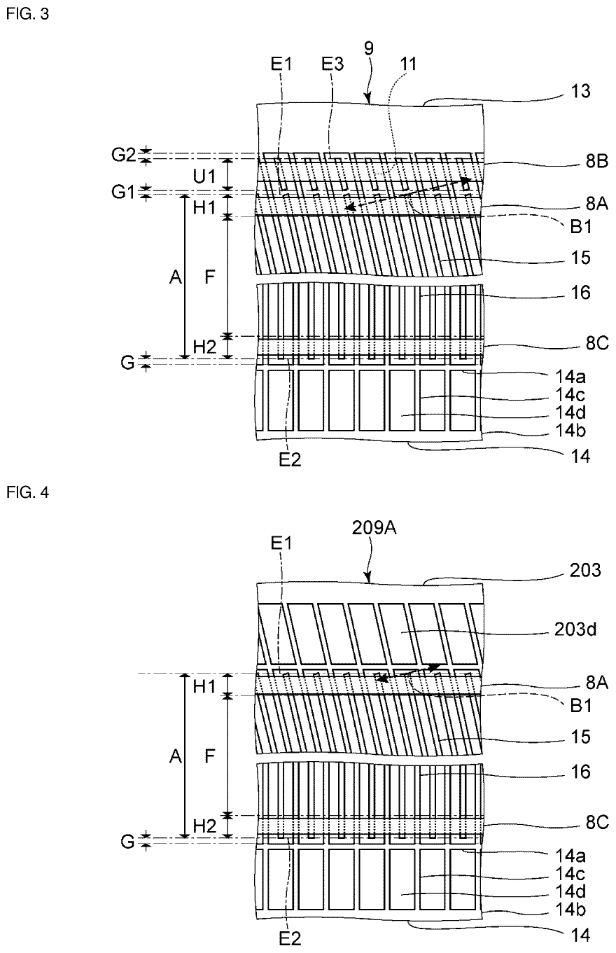

FIG. 3 is a schematic enlarged plan view illustrating the vicinity of an area enclosed by a dash-dot-dot line C in FIG. 1. The dielectric film 19 is omitted in FIG. 3.

The IDT electrode 9 includes a pair of busbars and a plurality of electrode fingers. The pair of busbars include, specifically, a first busbar 13 and a second busbar 14. The first busbar 13 and the second busbar 14 face each other. The plurality of electrode fingers include, specifically, a plurality of first electrode fingers 15 and a plurality of second electrode fingers 16. The plurality of first electrode fingers 15 each include one end portion connected to the first busbar 13. The plurality of second electrode fingers 16 each include one end portion connected to the second busbar 14. The plurality of first electrode fingers 15 and the plurality of second electrode fingers 16 are interdigitated with each other.

The second busbar 14 includes a plurality of apertures 14d. More specifically, the second busbar 14 includes an inner busbar portion 14a, an outer busbar portion 14b, and a plurality of connection portions 14c. The inner busbar portion 14a and the outer busbar portion 14b face each other. Of the inner busbar portion 14a and the outer busbar portion 14b, the inner busbar portion 14a is located on the first busbar 13 side. The plurality of connection portions 14c connect the inner busbar portion 14a and the outer busbar portion 14b. The plurality of apertures 14d are each surrounded by the inner busbar portion 14a, the outer busbar portion 14b, and the plurality of connection portions 14c.

The inner busbar portion 14a and the outer busbar portion 14b extend parallel or substantially parallel to each other. Therefore, the distance between the inner busbar portion 14a and the outer busbar portion 14b is constant. Specifically, an aperture length of the plurality of apertures 14d is constant, where the aperture length is the dimension of the plurality of apertures 14d in a direction orthogonal or substantially orthogonal to the extending direction of the inner busbar portion 14a. On the other hand, for example, no apertures are provided in the first busbar 13.

Hereinafter, the first electrode fingers 15 and the second electrode fingers 16 may be simply referred to as electrode fingers. The first busbar 13 and the second busbar 14 may be simply referred to as busbars.

The shapes of the plurality of first electrode fingers 15 and the plurality of second electrode fingers 16 in plan view include curved shapes. As used herein, the term “plan view” refers to a view seen from a direction corresponding to the upper side in FIG. 2. In FIG. 2, for example, of the support substrate 4 side and the piezoelectric layer 6 side, the piezoelectric layer 6 side is the upper side. Furthermore, as used herein, the term “plan view” is synonymous with a view seen from a main surface facing direction. The main surface facing direction is the direction in which the first main surface 6a and the second main surface 6b of the piezoelectric layer 6 face each other. More specifically, the main surface facing direction is, for example, a normal direction to the first main surface 6a.

In the present example embodiment, specifically, the shapes of the plurality of first electrode fingers 15 and the plurality of second electrode fingers 16 in plan view are curved shapes. In example embodiments of the present invention, the shapes of the plurality of first electrode fingers 15 and the plurality of second electrode fingers 16 in plan view may include a curved portion and a linear portion. Alternatively, the shapes may be linear.

The plurality of first electrode fingers 15 and the plurality of second electrode fingers 16 illustrated in FIG. 3 each include a base end portion, a tip end portion, and a pair of edge portions. Specifically, the base end portion of the first electrode finger 15 is a portion connected to the first busbar 13. The pair of edge portions of the first electrode finger 15 are portions connecting the base end portion and the tip end portion. The base end portion of the second electrode finger 16 is a portion connected to the second busbar 14. The pair of edge portions of the second electrode finger 16 are portions connecting the base end portion and the tip end portion.

The tip end portions of the plurality of first electrode fingers 15 and the plurality of second electrode fingers 16 each include a tip end. A virtual line connecting the tip ends of the plurality of second electrode fingers 16 is referred to as a first envelope E1. Similarly, a virtual line connecting the tip ends of the plurality of first electrode fingers 15 is referred to as a second envelope E2.

In the present example embodiment, an extending direction of the first envelope E1 and an extending direction of the second envelope E2 are parallel or substantially parallel to each other. The extending directions of the first envelope E1 and the second envelope E2 are parallel or substantially parallel to the extending direction of the propagation axis. The extending direction of the first envelope E1 intersects with, but is not orthogonal to, the extending direction of the plurality of first electrode fingers 15 and the plurality of second electrode fingers 16. Similarly, the extending direction of the second envelope E2 intersects with, but is not orthogonal to, the extending direction of the plurality of first electrode fingers 15 and the plurality of second electrode fingers 16. The extending direction of the first envelope E1 and the extending direction of the second envelope E2 may intersect with each other.

The region between the first envelope E1 and the second envelope E2 is an intersection region A. More specifically, the intersection region A is the region surrounded by the edge portions of the plurality of electrode fingers at one end portion in the direction in which the electrode fingers are arranged, the edge portions of the electrode fingers at the other end portion, the first envelope E1, and the second envelope E2. Therefore, the first envelope E1 corresponds to the edge portion of the intersection region A on the first busbar 13 side. The second envelope E2 corresponds to the edge portion of the intersection region A on the second busbar 14 side. In the intersection region A, adjacent electrode fingers overlap with each other when viewed from the extending direction of the first envelope E1 or the second envelope E2.

In the present example embodiment, the intersection region A includes a single curved region. The curved region is a region in which the shapes of the first electrode fingers 15 and the second electrode fingers 16 are each curved in plan view. One edge of the curved region that defines the intersection region A is the first envelope E1, and the other edge is the second envelope E2.

By applying an alternating-current (AC) voltage to the IDT electrode 9, acoustic waves are excited in the intersection region A. More specifically, for example, an SH mode is excited as a main mode. In this case, Rayleigh waves are unwanted waves. However, the main mode is not limited to the SH mode.

In the intersection region A, the excitation direction of acoustic waves in any portion of any of the plurality of electrode fingers is one of the following first, second, and third directions. The first direction is perpendicular or substantially perpendicular to the extending direction of the electrode finger. The second direction is the direction in which the distance between the electrode finger and the first electrode finger 15 or the second electrode finger 16 adjacent to the electrode finger is shortest. The third direction is the direction of an electric field vector generated between the electrode finger and the first electrode finger 15 or the second electrode finger 16 adjacent to the electrode finger.

In FIG. 3, an example of the acoustic wave propagation direction is indicated by a double-headed arrow B1. Strictly speaking, the acoustic wave excitation direction and the acoustic wave propagation direction may differ from each other. However, in example embodiments of the present invention, even if the acoustic wave excitation direction and the acoustic wave propagation direction are the same, it does not create any significant problem. Therefore, in this specification, the acoustic wave excitation direction and the acoustic wave propagation direction will be treated as the same direction.

Since the shape of each electrode finger in the intersection region A is the curved shape, the extending direction of each electrode finger varies depending on the position. In this specification, unless otherwise specified, the extending direction of the curved electrode fingers will be defined as follows.

First, a pair of edge portions of each electrode finger has a curved shape. When a virtual line is drawn parallel or substantially parallel to the extending direction of the propagation axis at any portion of the electrode finger so as to connect both edge portions, the center of gravity of the portion located on the virtual line is the representative point of the virtual line. Countless virtual lines can be drawn on the electrode finger, and therefore countless representative points exist. An extending direction of a tangent to a curve connecting these representative points is the extending direction of the electrode finger.

An excitation angle θ_{C_prop} is the angle between the acoustic wave excitation direction and the extending direction of the propagation axis of the piezoelectric layer 6. In the present example embodiment, the shape of each electrode finger in the intersection region A in plan view is curved. Therefore, the excitation angle θ_{C_prop} is not uniform in the intersection region A. For this reason, the acoustic wave excitation direction is not uniform in the intersection region A.

Referring back to FIG. 1, in the present example embodiment, a portion through which the second envelope E2 passes is the portion where the excitation angle θ_{C_prop} is 0°. The portions where the excitation angle θ_{C_prop} is 0° are arranged linearly. On the other hand, as indicated by a curve M, in the present example embodiment, when portions where the excitation angle θ_{C_prop} is other than 0° and the excitation angle θ_{C_prop} is the same are connected, a curved shape is provided. In other words, the curve M is the line connecting the portions where the acoustic wave excitation direction is the same.

However, the curve M is an example of the portion where the excitation angle θ_{C_prop} is other than 0° and the excitation angle θ_{C_prop} is the same. In the intersection region A, there are countless curves the same as or similar to the curve M. Accordingly, the shape of the plurality of first electrode fingers 15 and the plurality of second electrode fingers 16 in plan view is such that the portions where the excitation angle θ_{C_prop} is other than 0° and the same are arranged in a curved line.

In this specification, the positive direction of the excitation angle θ_{C_prop} is the counterclockwise direction in plan view. In the present example embodiment, the excitation angle θ_{C_prop} is greater than or equal to 0° in all portions of the intersection region A. However, in the present invention, the intersection region A may include portions where the excitation angle θ_{C_prop} is less than 0°.

As illustrated in FIG. 3, the intersection region A includes a central region F and a pair of edge regions. The central region F is located on the center side of the intersection region A in a propagation orthogonal direction, the propagation orthogonal direction being the direction orthogonal or substantially orthogonal to the acoustic wave propagation direction. In the present example embodiment, the central region F is located on the center side of the intersection region A in the direction in which the first busbar 13 and the second busbar 14 face each other. The pair of edge regions include, specifically, a first edge region H1 and a second edge region H2. The first edge region H1 and the second edge region H2 face each other across the central region F.

The first edge region H1 is located on the first busbar 13 side. The first edge region H1 includes the first envelope E1 as its edge portion. The second edge region H2 is located on the second busbar 14 side. The second edge region H2 includes the second envelope E2 as its edge portion.

The range of the first edge region H1 and the second edge region H2 is based on λ, which is the wavelength determined by an electrode finger pitch. The electrode finger pitch is the center-to-center distance between the first electrode fingers 15 and the second electrode fingers 16 that are adjacent to each other. λ=2p, where p is the electrode finger pitch.

The first edge region H1 is a region in a range of about 1λ from the first envelope E1 in the direction normal to the first envelope E1. Similarly, the second edge region H2 is a region in a range of about 1λ from the second envelope E2 in the direction normal to the second envelope E2. Additionally, the first edge region H1 and the second edge region H2 include all portions in the thickness direction of the acoustic wave device 10. For example, the intermediate layer 5 or the like illustrated in FIG. 2 also includes the first edge region H1 and the second edge region H2.

The electrode finger pitch p that determines the wavelength λ may be the narrowest electrode finger pitch in the portion where the excitation angle θ_{C_prop} is 0°. In the present example embodiment, the portion where the excitation angle θ_{C_prop} is 0° is the portion on the second envelope E2.

As illustrated in FIG. 3, the IDT electrode 9 further includes a plurality of floating electrodes. In the present example embodiment, the plurality of floating electrodes include, specifically, a plurality of first floating electrodes 11. The plurality of first floating electrodes 11 are located between the first edge region H1 and the first busbar 13. The plurality of first floating electrodes 11 are not connected to the first busbar 13, the second busbar 14, the plurality of first electrode fingers 15, or the plurality of second electrode fingers 16. The plurality of first floating electrodes 11 and the plurality of first electrode fingers 15 are alternately arranged. The region which is located between the first edge region H1 and the first busbar 13 and in which the plurality of first floating electrodes 11 are provided is a first floating electrode formation region U1.

More specifically, the first floating electrode formation region U1 is a strip-shaped region in which the plurality of first floating electrodes 11 and the plurality of first electrode fingers 15 are alternately arranged. The first floating electrode formation region U1 includes all of the portions in the thickness direction of the acoustic wave device 10. For example, the intermediate layer 5 or the like illustrated in FIG. 2 also includes the first floating electrode formation region U1.

As illustrated in FIG. 3, the tip end portion of each of the plurality of second electrode fingers 16 faces one end portion of one of the plurality of first floating electrodes 11 across a gap. A region where the gap between the plurality of second electrode fingers 16 and the plurality of first floating electrodes 11 is located is a first gap region G1. The other end portions of the plurality of first floating electrodes 11 face the first busbar 13 across a gap. A region where the gap between the plurality of first floating electrodes 11 and the first busbar 13 is located is a second gap region G2.

The shape of the plurality of first floating electrodes 11 in plan view is curved. Specifically, the shape of the plurality of first floating electrodes 11 in plan view is a shape that can be approximated to an arc. When the shape of any first floating electrode 11 and the shape of the second electrode finger 16 facing that first floating electrode 11 in plan view are each approximated to an arc, the respective arcs are included in the same circle.

The end portions of the plurality of first floating electrodes 11 on the first busbar 13 side are defined as tip end portions of the plurality of first floating electrodes 11. The tip end portions of the plurality of first floating electrodes 11 each include a tip end. A virtual line connecting the tip ends of the plurality of first floating electrodes 11 is a third envelope E3. In this case, a region between the third envelope E3 and the first busbar 13 is the second gap region G2.

An extending direction of the third envelope E3 intersects with, but is not orthogonal to, an extending direction of the plurality of first floating electrodes 11. Similarly, the extending direction of the first envelope E1 intersects with, but is not orthogonal to, the extending direction of the plurality of first floating electrodes 11.

When the dimension of the first gap region G1 in the direction normal to the first envelope E1 is the width of the first gap region G1, the width of the first gap region G1 is, for example, less than about 1λ in the present example embodiment. When the dimension of the second gap region G2 in the direction normal to the third envelope E3 is the width of the second gap region G2, the width of the second gap region G2 is, for example, less than about 1λ in the present example embodiment. However, the widths of the first gap region G1 and the second gap region G2 are not limited to the above.

In the present example embodiment, a plurality of floating electrodes are not provided on the second busbar 14 side. Therefore, the tip end portions of the plurality of first electrode fingers 15 face the second busbar 14 across a gap. A region where the gap between the plurality of first electrode fingers 15 and the first busbar 13 is located is a gap region G.

One mass addition film is provided in each of the first edge region H1, the first floating electrode formation region U1, and the second edge region H2. Specifically, a first mass addition film 8A is provided in the first edge region H1. A second mass addition film 8B is provided in the first floating electrode formation region U1. A third mass addition film 8C is provided in the second edge region H2.

The first mass addition film 8A has a band shape. The first mass addition film 8A is provided continuously over the plurality of electrode fingers. Similarly, the second mass addition film 8B and the third mass addition film 8C also have a band shape. The second mass addition film 8B is also provided continuously over the plurality of electrode fingers. Therefore, the first mass addition film 8A and the second mass addition film 8B are also provided in the areas between the electrode fingers on the piezoelectric layer 6. The third mass addition film 8C is provided continuously over the plurality of first floating electrodes 11 and the plurality of first electrode fingers 15. Therefore, the third mass addition film 8C is also provided in the areas between the first floating electrodes 11 and the first electrode fingers 15 on the piezoelectric layer 6.

Hereinafter, the dimension of the first mass addition film 8A in the direction normal to the first envelope E1 will be referred to as the width of the first mass addition film 8A. The dimension of the second mass addition film 8B in the direction normal to the third envelope E3 will be referred to as the width of the second mass addition film 8B. The dimension of the third mass addition film 8C in the direction normal to the second envelope E2 will be referred to as the width of the third mass addition film 8C.

Referring back to FIG. 1, a pair of reflectors are provided on the piezoelectric layer 6. The pair of reflectors include, specifically, a reflector 7A and a reflector 7B. The reflectors 7A and 7B face each other across the IDT electrode 9 in the direction in which the plurality of electrode fingers of the IDT electrode 9 are arranged.

The reflectors 7A and 7B each include a pair of reflector busbars and a plurality of reflector electrode fingers. In the reflector 7A, the plurality of reflector electrode fingers each include one end portion connected to one of the reflector busbars. The plurality of reflector electrode fingers each include the other end portion connected to the other reflector busbar. The same applies to the reflector 7B.

The shape of the plurality of reflector electrode fingers of the reflectors 7A and 7B in plan view includes a curved shape. Specifically, the plurality of reflector electrode fingers in the reflectors 7A and 7B have a shape corresponding to the plurality of electrode fingers of the IDT electrode 9. This allows the reflectors 7A and 7B to effectively reflect acoustic waves toward the IDT electrode 9.

More specifically, in the reflectors 7A and 7B, the plurality of reflector electrode fingers have a curved shape so that portions of the intersection region A in the same acoustic wave propagation direction are aligned in a trajectory continuous with a trajectory in which portions in the same acoustic wave excitation direction are aligned. However, the shape of the plurality of reflector electrode fingers of the reflectors 7A and 7B is not limited to the above.

In the present example embodiment, the first mass addition film 8A is provided in the first edge region H1 and the second mass addition film 8B is provided in the first floating electrode formation region U1. This makes it possible to reduce or prevent a transverse mode and reduce the leakage of acoustic wave energy. This will be described in detail below by comparing the present example embodiment with a first comparative example.

The first comparative example illustrated in FIG. 4 differs from the first example embodiment in that an IDT electrode 209A does not include a plurality of floating electrodes and a first busbar 203 includes a plurality of apertures 203d. In the first comparative example, a plurality of second electrode fingers 16 face a first busbar 203 across a gap. A first mass addition film 8A is provided in a first edge region H1. A third mass addition film 8C is provided in a second edge region H2.

The acoustic wave device 10 having the configuration of the first example embodiment and an acoustic wave device of the first comparative example are prepared and compared for impedance-frequency characteristics and return loss. The design parameters of the acoustic wave device 10 having the configuration of the first example embodiment are as follows. Here, the dimension of a floating electrode in the extending direction of the floating electrode is the length of the floating electrode. The dimension of an inner busbar portion of a busbar including a plurality of apertures in a direction orthogonal or substantially orthogonal to the extending direction of the inner busbar portion is the width of the inner busbar portion.

Support substrate: Material . . . Si, Surface orientation . . . (111), ψ of Euler angles (φ, θ, ψ) . . . about 73°

First layer of intermediate layer: Material . . . SiN, Thickness . . . about 0.15λ

Second layer of intermediate layer: Material . . . SiO₂, Thickness . . . about 0.15λ

Piezoelectric layer: Material . . . Rotated Y-cut 55° X-propagating LiTaO₃, Thickness . . . about 0.2λ

IDT electrode: Material . . . Al, Thickness . . . about 0.05λ

Dielectric film: Material . . . SiO₂, Thickness . . . about 0.02λ

Wavelength λ: about 2 μm where excitation angle θ_{C_prop} is 0°

Number of pairs of electrode fingers of IDT electrode: 90 pairs

Distance between first envelope and second envelope: about 27.8λ

Duty ratio: about 0.5 where excitation angle θ_{C_prop} is 0°

Number of pairs of reflector electrode fingers in each reflector: 20 pairs

Width of first mass addition film: about 0.72λ

Width of first gap region: about 0.135λ

Length of first floating electrode: about 1λ

Width of second mass addition film: about 0.72λ

Width of second gap region: about 0.135λ

Width of third mass addition film: about 0.62λ

Width of inner busbar portion of second busbar: about 0.2λ.

Aperture length of aperture in second busbar: about 2λ.

In this example, the first mass addition film and the second mass addition film have the same or substantially the same width. However, the first mass addition film and the second mass addition film may have different widths.

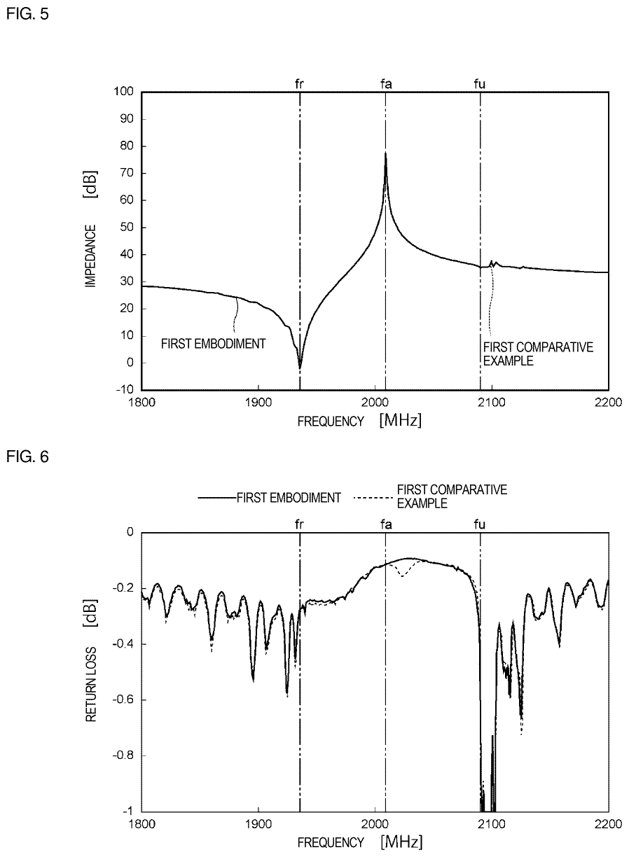

FIG. 5 is a graph illustrating impedance-frequency characteristics in the first example embodiment and the first comparative example. FIG. 6 is a graph illustrating return loss in the first example embodiment and the first comparative example.

As illustrated in FIG. 5, there is little difference in the impedance-frequency characteristics between the first example embodiment and the first comparative example. Therefore, the fractional bandwidth is the same or substantially the same between the first example embodiment and the first comparative example. The fractional bandwidth is expressed as (|fa−fr|/fr)×100 [%], where fr is the resonant frequency and fa is the anti-resonant frequency.

In addition, the electrostatic capacitance is also the same or substantially the same between the first example embodiment and the first comparative example. More specifically, the electrostatic capacitance correlates with the impedance at frequencies lower than the resonant frequency fr. The impedance at frequencies lower than the resonant frequency fr is the same or substantially the same between the first example embodiment and the first comparative example. Therefore, the electrostatic capacitance is also the same or substantially the same between the first example embodiment and the first comparative example.

As illustrated in FIG. 6, the transverse mode is reduced or prevented in the first example embodiment and the first comparative example. The transverse mode is an unwanted wave generated at frequencies between the resonant frequency fr and the anti-resonant frequency fa. The transverse mode is reduced or prevented for the following reason.

In the first example embodiment illustrated in FIG. 3, the first mass addition film 8A is provided in the first edge region H1, and thus the acoustic velocity in the first edge region H1 is lower than the acoustic velocity in the central region F. Accordingly, a low acoustic velocity region is provided in the first edge region H1. The low acoustic velocity region is a region where the acoustic velocity is lower than that in the central region F. A low acoustic velocity region is also provided in the second edge region H2 by providing the third mass addition film 8C. The same applies to the first comparative example.

In addition, of the plurality of first electrode fingers 15 and the plurality of second electrode fingers 16, only the plurality of first electrode fingers 15 are provided in the first gap region G1 of the first example embodiment. On the other hand, in the intersection region A, the first electrode fingers 15 and the second electrode fingers 16 are alternately arranged. Therefore, the acoustic velocity in the first gap region G1 is higher than that in the intersection region A. Accordingly, a high acoustic velocity region is provided in the first gap region G1. The high acoustic velocity region is a region where the acoustic velocity is higher than that in the central region F. Similarly, a high acoustic velocity region is also provided in the gap region G on the second busbar 14 side.

On the other hand, in the first example embodiment, each of the plurality of connection portions 14c of the second busbar 14 extends on an extension of the second electrode finger 16. None of the plurality of connection portions 14c is provided on an extension of the first electrode finger 15. On the other hand, in the intersection region A, the first electrode fingers 15 and the second electrode fingers 16 are alternately arranged. Therefore, the acoustic velocity in the region of the second busbar 14 where the plurality of apertures 14d are provided is higher than the acoustic velocity in the intersection region A. Accordingly, a high acoustic velocity region is provided in the region of the second busbar 14 where the plurality of apertures 14d are provided.

In the first comparative example illustrated in FIG. 4, high acoustic velocity regions are provided in a region where a gap is located between the plurality of second electrode fingers 16 and the first busbar 203, and in a region where a gap is located between the plurality of first electrode fingers 15 and the second busbar 14. High acoustic velocity regions are also provided in the region where the plurality of apertures 203d of the first busbar 203 are provided, and in the region where the plurality of apertures 14d of the second busbar 14 are provided.

In the first example embodiment, the central region F, a pair of low acoustic velocity regions, and a pair of high acoustic velocity regions are arranged in this order from the inner side portion to the outer side portion in the direction in which the first busbar 13 and the second busbar 14 face each other. This makes it easier to confine acoustic wave energy in the intersection region A. Furthermore, transverse standing waves generated in the intersection region A can be converted into vibration modes that are pseudo-free ends at both lateral edges of the intersection region A. The lateral edges of the intersection region A are, specifically, the edge on the first edge region H1 side and the edge on the second edge region H2 side. Accordingly, the transverse mode can be reduced or prevented. The same applies to the first comparative example.

However, in the first comparative example, large ripples are generated within a stop band in the return loss characteristics. The stop band is a region where the wavelength of an acoustic wave is constant due to the acoustic wave being confined by a periodic metal grating. The upper end of the stop band, that is, the highest frequency in the stop band is designated as fu. On the other hand, the lower end of the stop band, that is, the lowest frequency in the stop band coincides with the resonant frequency fr. In the first comparative example, specifically, a large ripple is generated between the upper end fu of the stop band and the anti-resonant frequency fa.

As described above, when the central region F, the low acoustic velocity region, and the high acoustic velocity region are arranged in this order, the acoustic wave energy is easily confined in the intersection region A. However, some of the acoustic waves leak outside of the intersection region A. In the first comparative example illustrated in FIG. 4, the first edge region H1, the region where the gap is located between the plurality of second electrode fingers 16 and the first busbar 203, the inner busbar portion, and the region where the plurality of apertures 203d are provided are arranged in this order. Some of the acoustic waves travel from the region where the gap is located between the plurality of second electrode fingers 16 and the first busbar 203 toward the inner busbar portion and the region where the plurality of apertures 203d are provided.

The acoustic velocity is low in the inner busbar portion. On the other hand, a high acoustic velocity region is provided in the region where the plurality of apertures 203d are provided. The acoustic waves leaked outside of the intersection region A are thus reflected toward the intersection region A. The reflected acoustic waves travel toward the second edge region H2 and the second busbar 14. The acoustic waves reflected between the regions with different acoustic velocities are not easily reflected on the second edge region H2 side and the second busbar 14 side. Therefore, in the first comparative example, acoustic wave leakage cannot be sufficiently reduced or prevented. This results in a large ripple between the upper end fu of the stop band and the anti-resonant frequency fa, as illustrated in FIG. 6.

In the first example embodiment, on the other hand, there is no ripple between the upper end fu of the stop band and the anti-resonant frequency fa. This is because of the following reason.

As illustrated in FIG. 3, the plurality of first floating electrodes 11 are provided, across the first gap region G1, outside the intersection region A. In the first example embodiment, the extending direction of the first envelope E1 intersects with, but is not orthogonal to, the extending direction of the plurality of first electrode fingers 15 and the plurality of second electrode fingers 16. Therefore, acoustic waves leaked outside of the intersection region A reach the region where the plurality of first floating electrodes 11 and the plurality of first electrode fingers 15 are alternately arranged, that is, the first floating electrode formation region U1. The plurality of first floating electrodes 11 and the plurality of first electrode fingers 15 can reflect the acoustic waves leaked outside of the intersection region A toward the intersection region A. This reflection is not the reflection between the regions with different acoustic velocities. Therefore, the acoustic waves reflected by the plurality of first floating electrodes 11 and the plurality of first electrode fingers 15 do not easily leak on the second busbar 14 side.

In addition, the second mass addition film 8B is provided in the first floating electrode formation region U1. Accordingly, a low acoustic velocity region is provided in the first floating electrode formation region U1. In the second gap region G2, of the plurality of first electrode fingers 15 and the plurality of second electrode fingers 16, only the plurality of first electrode fingers 15 are provided. Accordingly, a high acoustic velocity region is provided in the second gap region G2. The low acoustic velocity region provided in the first floating electrode formation region U1 and the high acoustic velocity region provided in the second gap region G2 are arranged in this order. This allows acoustic waves that are not reflected by the plurality of first floating electrodes 11 and the plurality of first electrode fingers 15 to be reflected toward the intersection region A.

However, the acoustic waves leaked outside of the intersection region A reach the first floating electrode formation region U1 before reaching the boundary between the first floating electrode formation region U1 and the second gap region G2. This allows the acoustic waves to be effectively reflected by the plurality of first floating electrodes 11 and the plurality of first electrode fingers 15. Therefore, acoustic waves leaked from the intersection region A toward the first busbar 13 and then reflected back to the intersection region A are suitably reflected on the second edge region H2 side and the second busbar 14 side. This makes it possible to effectively reduce or prevent the acoustic wave energy leakage. The first example embodiment can thus achieve both reduction or prevention of the transverse mode and reduction or prevention in acoustic wave energy leakage.

As in the first example embodiment, it is preferable that the extending direction of the first envelope E1 intersects with, but is not orthogonal to, the extending direction of the plurality of first floating electrodes 11. This allows the acoustic wave reflection characteristics within the IDT electrode 9 to be at least closer to the acoustic wave reflection characteristics in the region where the plurality of first floating electrodes 11 and the plurality of first electrode fingers 15 are alternately arranged. This allows acoustic waves to be more reliably reflected in this region.

Further description will be provided of the advantageous effects that the acoustic wave energy leakage can be reduced or prevented in the first floating electrode formation region U1. The first example embodiment is compared with a second comparative example.

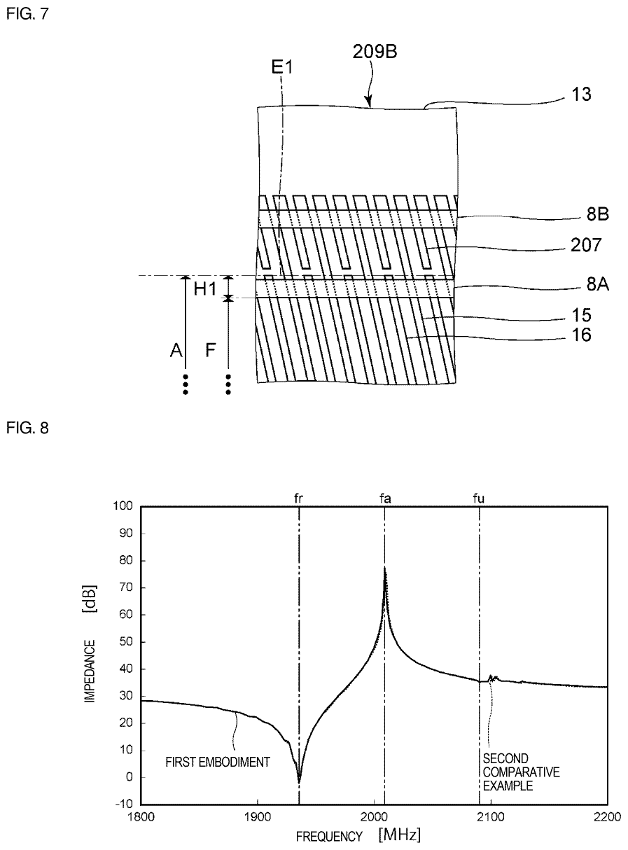

The second comparative example illustrated in FIG. 7 differs from the first example embodiment in that an IDT electrode 209B does not include a plurality of floating electrodes but includes a plurality of first offset electrodes 207, and in the position where a second mass addition film 8B is provided. The second comparative example also differs from the first example embodiment in that no second gap region is provided. The plurality of first offset electrodes 207 each include one end portion connected to a first busbar 13. The plurality of first offset electrodes 207 each include the other end portion facing the tip end portion of one of the plurality of second electrode fingers 16 across a gap. The second mass addition film 8B is provided over the plurality of first offset electrodes 207.

The acoustic wave device 10 having the configuration of the first example embodiment and an acoustic wave device of the second comparative example are prepared and compared for impedance-frequency characteristics and return loss. The design parameters of the acoustic wave device 10 having the configuration of the first example embodiment are the same or substantially the same as those used in the comparison illustrated in FIGS. 5 and 6.

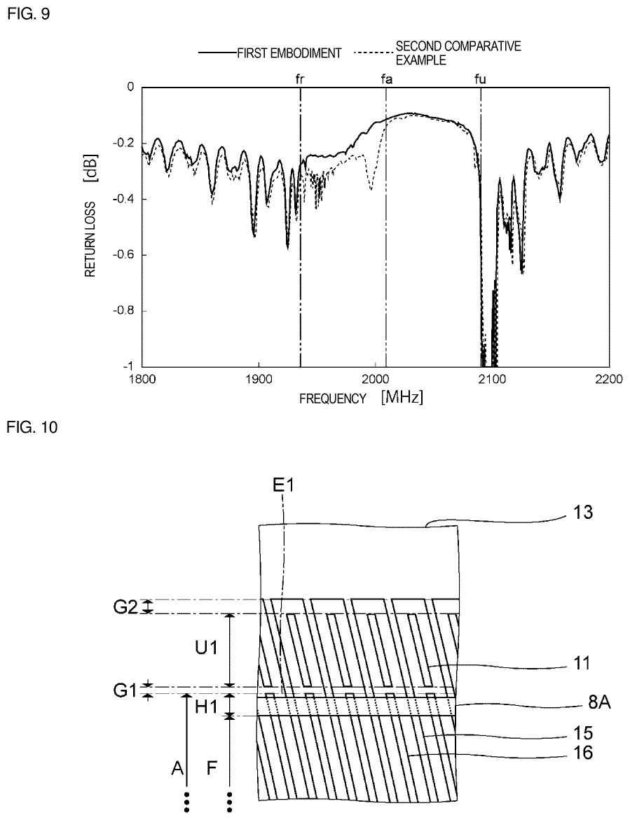

FIG. 8 is a graph illustrating impedance-frequency characteristics in the first example embodiment and the second comparative example. FIG. 9 is a graph illustrating return loss in the first example embodiment and the second comparative example.

As illustrated in FIG. 8, there is little difference in the impedance-frequency characteristics between the first example embodiment and the second comparative example. Therefore, the fractional bandwidth and electrostatic capacitance are the same or substantially the same between the first example embodiment and the second comparative example.

On the other hand, in the second comparative example as illustrated in FIG. 9, there is a large loss in a band between the resonant frequency fr and the anti-resonant frequency fa. There is also a large ripple near the anti-resonant frequency fa in this band.

In the first example embodiment, on the other hand, the loss is small between the resonant frequency fr and the anti-resonant frequency fa, and the ripple is reduced or prevented. This is because, in the first example embodiment illustrated in FIG. 3, the second gap region G2 is provided and the high acoustic velocity region is provided in that region. The low acoustic velocity region provided in the first floating electrode formation region U1 and the high acoustic velocity region provided in the second gap region G2 are arranged in this order. This allows acoustic waves leaked from the intersection region A to be reflected toward the intersection region A. This makes it possible to reduce or prevent the acoustic wave energy leakage and reduce or prevent the loss in the first example embodiment. The ripple can also be reduced or prevented.

The first example embodiment is further compared with a third comparative example and a fourth comparative example.

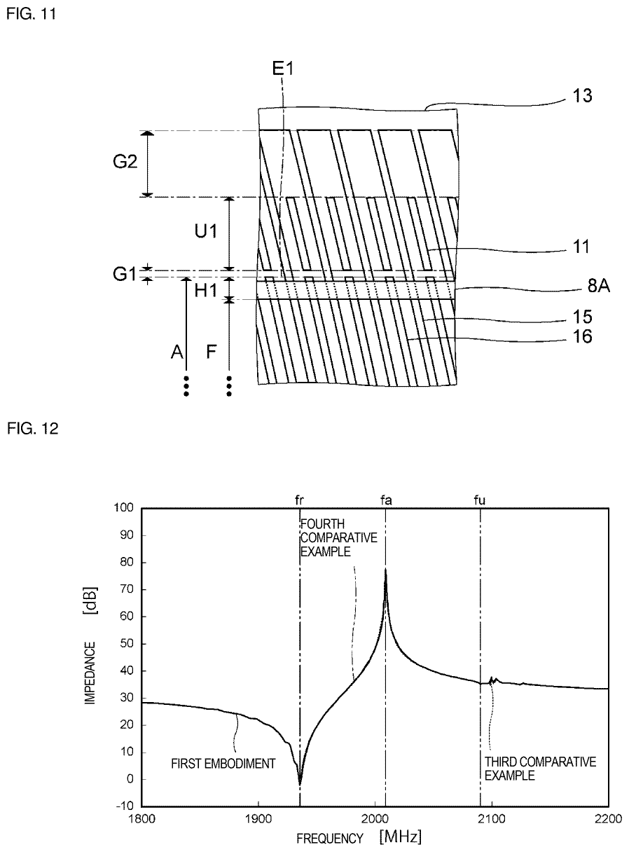

The third comparative example illustrated in FIG. 10 differs from the first example embodiment in not including a second mass addition film. The fourth comparative example illustrated in FIG. 11 differs from the first example embodiment in not including a second mass addition film and in that the width of the second gap region G2 is greater than or equal to about 1λ, for example. The width of the second gap region G2 in the third comparative example is the same or substantially the same as the width of the second gap region G2 in the first example embodiment.

The acoustic wave device 10 having the configuration of the first example embodiment and acoustic wave devices of the third and fourth comparative examples are prepared and compared for impedance-frequency characteristics and return loss. The design parameters of the acoustic wave device 10 having the configuration of the first example embodiment are the same or substantially the same as those used in the comparison illustrated in FIGS. 5 and 6.

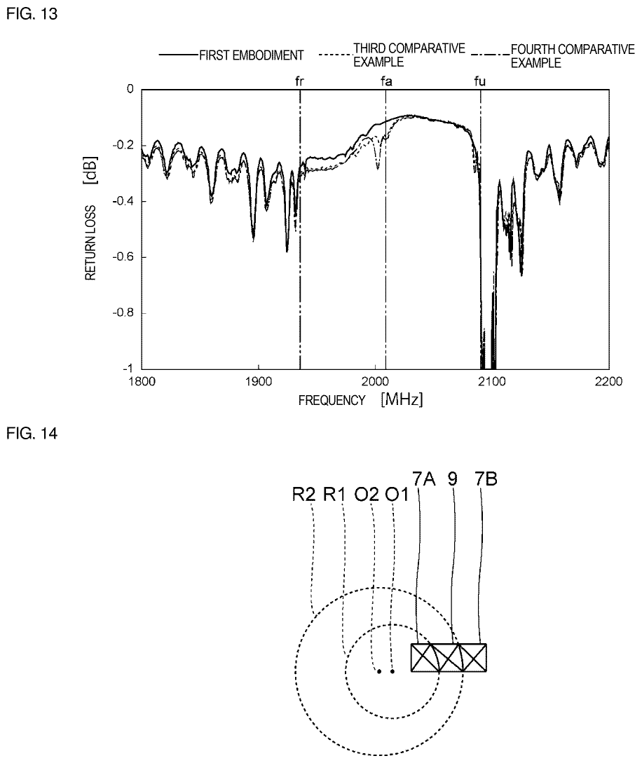

FIG. 12 is a graph illustrating impedance-frequency characteristics in the first example embodiment, the third comparative example, and the fourth comparative example. FIG. 13 is a graph illustrating return loss in the first example embodiment, the third comparative example, and the fourth comparative example.

As illustrated in FIG. 12, there is little difference in impedance-frequency characteristics between the first example embodiment, the third comparative example, and the fourth comparative example. Therefore, the fractional bandwidth and electrostatic capacitance are the same or substantially the same between the first example embodiment, the third comparative example, and the fourth comparative example.

On the other hand, in the third comparative example and the fourth comparative example as illustrated in FIG. 13, there is a large loss in a band between the resonant frequency fr and the anti-resonant frequency fa. There is also a large ripple near the anti-resonant frequency fa in this band. The ripple is particularly large in the fourth comparative example.

In the first example embodiment, on the other hand, the loss is small between the resonant frequency fr and the anti-resonant frequency fa, and the ripple is reduced or prevented. This is because, in the first example embodiment illustrated in FIG. 3, the second mass addition film 8B is provided in the first floating electrode formation region U1 and the low acoustic velocity region is provided in this region. The low acoustic velocity region provided in the first floating electrode formation region U1 and the high acoustic velocity region provided in the second gap region G2 are arranged in this order. This allows acoustic waves leaked from the intersection region A to be reflected toward the intersection region A. This makes it possible to reduce or prevent the acoustic wave energy leakage and reduce or prevent the loss in the first example embodiment. The ripple can also be reduced or prevented.

In the first example embodiment, the plurality of electrode fingers of the IDT electrode 9 have the curved shape in plan view. Accordingly, as described above, the excitation direction and the excitation angle θ_{C_prop} of the acoustic waves are not uniform in the intersection region A in the first example embodiment. Specifically, in the intersection region A, countless curved portions with the same excitation angle θ_{C_prop} other than 0° are arranged in the direction in which the first busbar 13 and the second busbar 14 face each other. The excitation angles θ_{C_prop} differ among these curved portions.

The portion with different excitation angles θ_{C_prop} have different propagation characteristics of unwanted waves. This allows unwanted waves to be dispersed and effectively reduced or prevented. In particular, unwanted waves outside the band, such as Rayleigh waves, can be reduced or prevented. As used herein, “outside the band” in the acoustic wave device refers to a frequency range lower than the resonant frequency of the main mode and higher than the anti-resonant frequency.

In the first example embodiment, the resonant frequencies or anti-resonant frequencies of the main mode of the acoustic wave device 10 match or substantially match in the intersection region A. This makes it possible to effectively reduce or prevent unwanted waves and more reliably improve resonance characteristics.

More specifically, in the portions of the intersection region A that differ from each other in the excitation angle θ_{C_prop}, the relationships between the resonant frequencies of the main mode and unwanted waves and between the anti-resonant frequencies are different. Therefore, when the resonant frequencies or anti-resonant frequencies of the main mode match or substantially match in each portion of the intersection region A, the resonant frequencies or anti-resonant frequencies of the unwanted waves are different from each other. Accordingly, the unwanted waves are dispersed. Therefore, the unwanted waves can be reduced or prevented.

In addition, since the resonant frequencies or anti-resonant frequencies of the main mode match or substantially match in the intersection region A, the main mode is suitably excited. Accordingly, the resonance characteristics can be more reliably improved.

As used herein, the expression “one frequency and the other frequency match or substantially match” means that the absolute value of the difference between the two frequencies is less than or equal to about 10% of a reference frequency, for example. The reference frequency refers to the frequency when the excitation angle θ_{C_prop} is 0°.

In the intersection region A, for example, it is preferable that the absolute value of the difference between the highest and lowest resonant frequencies of the main mode is less than or equal to about 1% of the reference frequency. Alternatively, in the intersection region A, for example, it is preferable that the absolute value of the difference between the highest and lowest anti-resonant frequencies of the main mode is less than or equal to about 1% of the reference frequency. Accordingly, the resonance characteristics can be more reliably improved.

It is preferable that the resonant frequencies or anti-resonant frequencies of the main mode match or substantially match in at least a portion of the intersection region A. It is even more preferable that the resonant frequencies or anti-resonant frequencies of the main mode match or substantially match in the entire or substantially the entire intersection region A. This further ensures that unwanted waves are dispersed and reduced or prevented more reliably. In addition, the resonance characteristics can be more reliably improved.

In the first example embodiment, the plurality of electrode fingers of the IDT electrode 9 have the curved shape in plan view. Therefore, in the intersection region A, countless curved portions are arranged with the same excitation angle θ_{C_prop} other than 0°. The configuration of the plurality of electrode fingers will be described in more detail below.

In the IDT electrode 9 illustrated in FIG. 1, the plurality of first electrode fingers 15 and the plurality of second electrode fingers 16 have shapes in plan view with a gradually changing curvature. Therefore, in the intersection region A, the curvature of each of the first electrode fingers 15 and the second electrode fingers 16 is not constant. Specifically, the shapes of the plurality of first electrode fingers 15 and the plurality of second electrode fingers 16 in plan view can each be approximated to an arc. However, for example, the shapes of the plurality of first electrode fingers 15 and the plurality of second electrode fingers 16 in plan view can each also be approximated to an elliptical arc. Alternatively, for example, the shape of each electrode finger in plan view can be a parabolic shape that cannot be approximated to an arc or an elliptical arc.

The curvature is a quantity representing the degree of bending of a curve or curved surface. The radius of a locally approximated arc at any point on a curve can be calculated, and the reciprocal of that radius can be expressed as the curvature. That is, the curvature is 1/r, where r is the calculated radius.

For the plurality of electrode fingers in the first example embodiment, adjacent portions are defined as follows. Specifically, the adjacent portion of a first electrode finger 15 is the portion of the first electrode finger 15 that includes a portion located on the first envelope E1 and is adjacent to the tip end portion of any of the second electrode fingers 16. The adjacent portion of a second electrode finger 16 is the portion of the second electrode finger 16 that includes a portion located on the second envelope E2 and is adjacent to the tip end portion of any of the first electrode fingers 15.

The tip end portion of an electrode finger is, for example, a portion within a range of about 1λ from the tip of the electrode finger in the extending direction of the electrode finger. The adjacent portion is also defined as, for example, a portion within a range of about 1λ in the extending direction of the electrode finger. The first edge region H1 is a region where the tip end portion of the second electrode finger 16 and the adjacent portion of the first electrode finger 15 are located. The second edge region H2 is a region where the tip end portion of the first electrode finger 15 and the adjacent portion of the second electrode finger 16 are located.

It is preferable that the shapes of all electrode fingers of the IDT electrode 9 in plan view are different curved shapes. Three specific examples of this will be described below. As a first example, it is preferable that the curvature differ between the tip end portions, between the adjacent portions, or between the tip end portions and the adjacent portions, of all of the first electrode fingers 15 and all of the second electrode fingers 16 located on the first envelope E1 side. More specifically, it is preferable that the curvature differs between the tip end portions of all second electrode fingers 16, between the adjacent portions of all of the first electrode fingers 15, and between the tip end portions of all of the second electrode fingers 16 and the adjacent portions of all of the first electrode fingers 15.

As a second example, it is preferable that the curvature differ between the tip end portions, between the adjacent portions, or between the tip end portions and the adjacent portions, of all first electrode fingers 15 and all second electrode fingers 16 that are located on the second envelope E2 side. More specifically, it is preferable that the curvature differs between the tip end portions of all first electrode fingers 15, between the adjacent portions of all second electrode fingers 16, and between the tip end portions of all first electrode fingers 15 and the adjacent portions of all second electrode fingers 16.

As a third example, it is preferable that the curvature differs between the portions of all first electrode fingers 15 and all second electrode fingers 16 located in the area where the excitation angle θ_{C_prop} is 0°. With all electrode fingers of the IDT electrode 9 having different curved shapes in plan view, unwanted waves can be more reliably and effectively reduced or prevented.

The first example embodiment satisfies all of the above three examples. However, it is sufficient that the curvature differs between the tip end portions, between the adjacent portions, or between the tip end portions and the adjacent portions, located on the first envelope E1 side, of at least one pair of electrode fingers among the plurality of first electrode fingers 15 and the plurality of second electrode fingers 16.

In the first example embodiment, the intersection region A includes a single curved region. In the first example embodiment, the shapes of the plurality of electrode fingers in plan view can each be approximated to an arc in the curved region. In other words, the shapes of the plurality of electrode fingers appear to be approximated to an arc in plan view. The shapes of the plurality of electrode fingers in plan view are also different curved shapes. Therefore, the relationship illustrated in FIG. 14 below is satisfied.

FIG. 14 is a schematic plan view illustrating a circle including an arc when the shape of the electrode fingers of the IDT electrode in plan view in the first example embodiment is approximated to an arc. In FIG. 14, the IDT electrode 9, the reflector 7A, and the reflector 7B are illustrated as outlines with two diagonal lines added.

In FIG. 14, two circles R1 and R2 are indicated by dashed lines. The circles R1 and R2 are circles including arcs when the shapes of two different electrode fingers in plan view are approximated to the arcs. The position of a center O1 of the circle R1 is different from the position of a center O2 of the circle R2.

In the curved region, it is preferable that when the shapes of all first electrode fingers 15 and all second electrode fingers 16 in plan view are approximated to arcs, the positions of the centers of the circles including those arcs are different from each other. In this case, as described above, the shapes of all electrode fingers of the IDT electrode 9 in plan view are different curved shapes.

In the first example embodiment, when the shapes of all first electrode fingers 15 and all second electrode fingers 16 in plan view are approximated to arcs, the positions of the centers of the circles including those arcs are different from each other. The reflector electrode fingers of the reflectors 7A and 7B each also have the same or substantially the same shape as that of each electrode finger of the IDT electrode 9. Specifically, when the shapes of all reflector electrode fingers of the reflectors 7A and 7B are approximated to arcs in plan view, the positions of the centers of the circles including the arcs are different from each other.

As described above, the shapes of the plurality of reflector electrode fingers of the reflectors 7A and 7B correspond to the shapes of the electrode fingers of the IDT electrode 9. This allows the reflectors 7A and 7B to effectively reflect acoustic waves toward the IDT electrode 9.

However, in the curved region, it is sufficient that when the shapes of at least one pair of electrode fingers among the plurality of first electrode fingers 15 and the plurality of second electrode fingers 16 of the IDT electrode 9 are approximated to arcs in plan view, the positions of the centers of the circles including the arcs are different from each other.

In the curved region, the shapes of the plurality of first electrode fingers 15 and the plurality of second electrode fingers 16 of the IDT electrode 9 in plan view may be capable of being approximated to elliptical arcs, for example. In this case, when the shapes of all first electrode fingers 15 and all second electrode fingers 16 of the IDT electrode 9 in plan view are approximated to elliptical arcs in the curved region, the positions of the centers of gravity of the ellipses including the elliptical arcs are preferably different from each other. The “center of gravity” here refers to the center of two foci of the ellipse. However, in the curved region, when the shapes of at least one pair of electrode fingers among the plurality of first electrode fingers 15 and the plurality of second electrode fingers 16 of the IDT electrode 9 in plan view are approximated to elliptical arcs, it is sufficient that the positions of the centers of gravity of the ellipses including the elliptical arcs are different from each other.

The line extending parallel or substantially parallel to the extending direction of the propagation axis is a reference line, the angle between the reference line and the first envelope E1 is an intersection angle θ_{C1_AP}, and the angle between the reference line and the second envelope E2 is an intersection angle θ_{C2_AP}. In the first example embodiment, the intersection angle θ_{C1_AP} and the intersection angle θ_{C2_AP} are both 0°. However, the intersection angle θ_{C1_AP} and the intersection angle θ_{C2_AP} are not limited to 0°.

Hereinafter, unless otherwise specified, the expression “resonant frequencies or anti-resonant frequencies match or substantially match” means that the resonant frequencies or anti-resonant frequencies of the main mode substantially match. In the first example embodiment, a duty ratio varies with the excitation angle θ_{C_prop} in the intersection region A. This allows the resonant frequencies to match or substantially match in the entire or substantially the entire intersection region A. More specifically, in the first example embodiment, the duty ratio is constant in a portion where the excitation angle θ_{C_prop} is the same or substantially the same. In at least a portion of the intersection region A, the duty ratio in a portion of the IDT electrode 9 where the excitation angle θ_{C_prop} is the same or substantially the same increases or decreases as the absolute value of the excitation angle θ_{C_prop} increases, so that the resonant frequencies or anti-resonant frequencies match or substantially match. However, the present invention is not limited thereto.

For example, the electrode finger pitch may be constant in the portion of the IDT electrode 9 where the excitation angle θ_{C_prop} is the same or substantially the same. The electrode finger pitch in the portion of the IDT electrode 9 where the excitation angle θ_{C_prop} is the same or substantially the same may become wider or narrower as the absolute value of the excitation angle θ_{C_prop} increases, so that the resonant frequencies or anti-resonant frequencies match or substantially match in at least a portion of the intersection region A.

Alternatively, in the portion of the IDT electrode 9 where the excitation angle θ_{C_prop} is the same or substantially the same, the thickness of the plurality of first electrode fingers 15 and the plurality of second electrode fingers 16 may be constant. The thickness of the plurality of first electrode fingers 15 and the plurality of second electrode fingers 16 in the portion where the excitation angle θ_{C_prop} is the same or substantially the same may vary, so that the resonant frequencies or anti-resonant frequencies match or substantially match in at least a portion of the intersection region A. Specifically, the thickness may increase or decrease as the absolute value of the excitation angle θ_{C_prop} increases.

It is preferable that at least one of the duty ratio, the electrode finger pitch, and the thickness of the plurality of first electrode fingers 15 and the plurality of second electrode fingers 16 is constant in the portion where the excitation angle θ_{C_prop} is the same or substantially the same, and varies with the excitation angle θ_{C_prop}. It is preferable that at least one of these parameters varies with the excitation angle θ_{C_prop}, so that the resonant frequencies or anti-resonant frequencies of the main mode match or substantially match in at least a portion of the intersection region A. It is even more preferable that at least one of these parameters varies with the excitation angle θ_{C_prop}, so that the resonant frequencies or anti-resonant frequencies of the main mode match or substantially match in the entire or substantially the entire intersection region A. In these cases, the resonance characteristics of the acoustic wave device 10 can be more reliably improved.

Alternatively, if the thickness of the intermediate layer 5 in the piezoelectric substrate 2 or the like affects the frequency, the parameter may be changed according to the excitation angle θ_{C_prop} in the intersection region A. If the dielectric film 19 is provided on the piezoelectric substrate 2 so as to cover the IDT electrode 9 as in the first example embodiment, the thickness of the dielectric film 19 may be changed according to the excitation angle θ_{C_prop} in the intersection region A. More than one of the above parameters of the IDT electrode 9 or parameters other than those of the IDT electrode 9 may be changed according to the excitation angle θ_{C_prop} in the intersection region A. In these cases, again, the resonant frequencies or anti-resonant frequencies of the main mode can match or substantially match in at least a portion or all of the intersection region A.

It is preferable that at least one of the electrode finger pitch and the duty ratio is constant in the portion of the IDT electrode 9 where the excitation angle θ_{C_prop} is the same or substantially the same. It is more preferable that both of the electrode finger pitch and the duty ratio are constant in the portion where the excitation angle θ_{C_prop} is the same or substantially the same. This makes it possible to more reliably improve the resonance characteristics of the acoustic wave device 10.

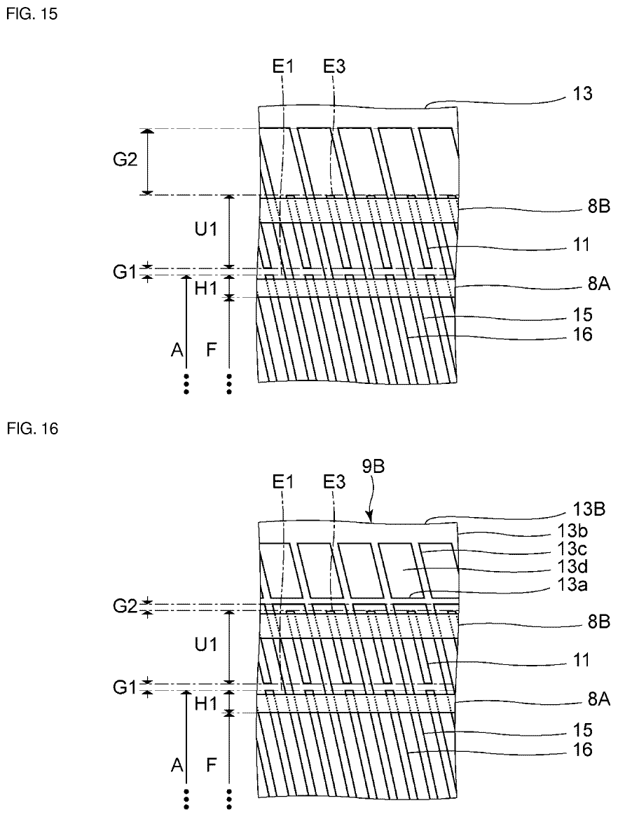

As described above, in the first example embodiment illustrated in FIG. 3, the width of the second gap region G2 is less than about 1λ, for example. However, the present invention is not limited thereto. For example, in a first modification of the first example embodiment illustrated in FIG. 15, the width of the second gap region G2 is greater than or equal to about 1λ. In this case, the dimension of the high acoustic velocity region formed in the second gap region G2 in the direction normal to the third envelope E3 can be increased. This makes it possible to more reliably confine the acoustic waves to the intersection region A side. In addition, as in the first example embodiment, a transverse mode can be reduced or prevented, and acoustic wave energy leakage from the second busbar side or the like can be reduced or prevented.

Referring back to FIG. 3, in the first example embodiment, no apertures are provided in the first busbar 13. The first busbar 13 may be configured in the same or substantially the same manner as the second busbar 14. For example, in a second modification of the first example embodiment illustrated in FIG. 16, a plurality of apertures 13d are provided in a first busbar 13B of an IDT electrode 9B. More specifically, the first busbar 13B includes an inner busbar portion 13a, an outer busbar portion 13b, and a plurality of connection portions 13c. The inner busbar portion 13a and the outer busbar portion 13b face each other. Of the inner busbar portion 13a and the outer busbar portion 13b, the inner busbar portion 13a is located on the intersection region A side. The plurality of connection portions 13c connect the inner busbar portion 13a and the outer busbar portion 13b. The plurality of apertures 13d are each surrounded by the inner busbar portion 13a, the outer busbar portion 13b, and the plurality of connection portions 13c.

The acoustic velocity in the region of the first busbar 13B where the plurality of apertures 13d are provided is higher than the acoustic velocity in the intersection region A, as in the region of the second busbar 14 where the plurality of apertures 14d are provided, as illustrated in FIG. 3. Accordingly, a high acoustic velocity region is provided in the region of the first busbar 13B where the plurality of apertures 13d are provided. In this case, acoustic waves can be more reliably confined to the intersection region A side. In addition, as in the first example embodiment, a transverse mode can be reduced or prevented, and acoustic wave energy leakage from the second busbar side or the like can be reduced or prevented in this modification.

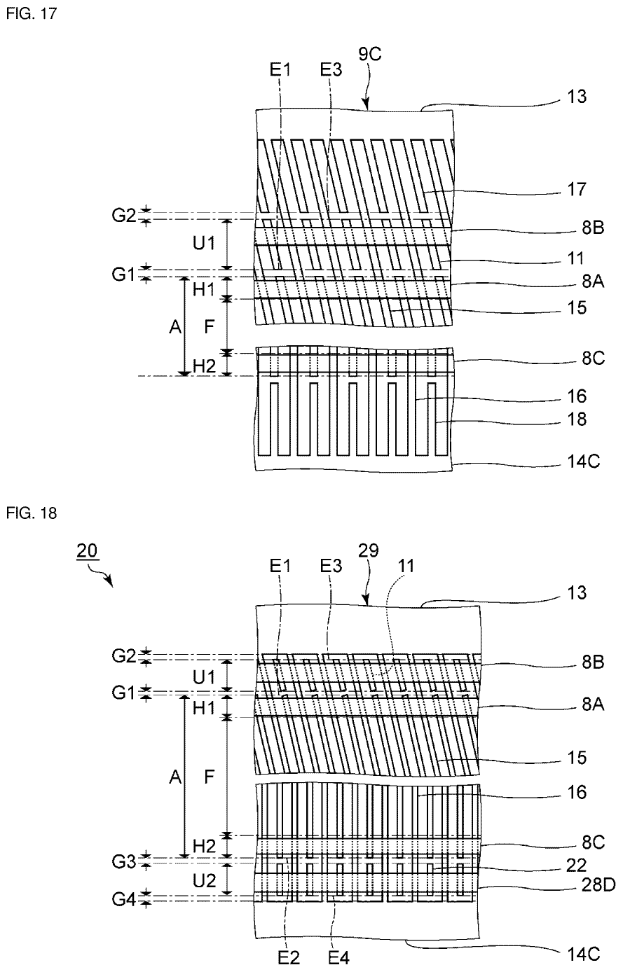

Alternatively, the IDT electrode 9 illustrated in FIG. 3 may include a plurality of offset electrodes. For example, in a third modification of the first example embodiment illustrated in FIG. 17, an IDT electrode 9C includes a plurality of offset electrodes. The plurality of offset electrodes of the IDT electrode 9C include, specifically, a plurality of first offset electrodes 17 and a plurality of second offset electrodes 18. The plurality of first offset electrodes 17 each include one end portion connected to the first busbar 13. The first electrode fingers 15 and the first offset electrodes 17 are alternately arranged.

The plurality of second offset electrodes 18 each include one end portion connected to a second busbar 14C. The second electrode fingers 16 and the second offset electrodes 18 are alternately arranged. No apertures are provided in the second busbar 14C.

As with the plurality of first electrode fingers 15 and the plurality of second electrode fingers 16, the plurality of first offset electrodes 17 and the plurality of second offset electrodes 18 each include a base end portion and a tip end portion. The base end portions of the first electrode fingers 15 and the first offset electrodes 17 are portions connected to the first busbar 13. The base end portions of the second electrode fingers 16 and the second offset electrodes 18 are portions connected to the second busbar 14C. The tip end portion of the first electrode finger 15 and the tip end portion of the second offset electrode 18 face each other across a gap. The tip end portion of the second electrode finger 16 and the tip end portion of the first offset electrode 17 face each other across a gap.

In this modification, the plurality of first offset electrodes 17 have a curved shape in plan view. Specifically, the shape of each first offset electrode 17 corresponds to the shape of the opposing second electrode finger 16. More specifically, the shape of the plurality of first offset electrodes 17 in plan view is a shape that can be approximated to an arc. When the shape of any first offset electrode 17 and the shape of the second electrode finger 16 facing that first offset electrode 17 in plan view are each approximated to an arc, the respective arcs are included in the same circle.

The tip end portions of all of the first offset electrodes 17 have different curvatures from each other. Accordingly, the conditions for the intersection region A where the main mode is excited and the conditions for the region where the plurality of first offset electrodes 17 are provided can be at least brought closer or matched. This makes it possible to effectively reflect the main mode to the intersection region A side. However, for example, the curvatures of the tip end portions of at least one pair of first offset electrodes 17 among the plurality of first offset electrodes 17 may be different from each other. In this case, again, the main mode can be effectively reflected to the intersection region A side.

Alternatively, for example, the plurality of first offset electrodes 17 may have a linear shape in plan view. In this case, the distance from the tip end portion of the first offset electrode 17 to the first busbar 13 can be reduced. This makes it possible to reduce electric resistance of the IDT electrode 9C. Therefore, in a case of using the acoustic wave device in a filter device, an increase in insertion loss can be reduced or prevented.

In this modification, the plurality of second offset electrodes 18 have a linear shape in plan view. Accordingly, the shape of each second offset electrode 18 corresponds to the shape of the opposing first electrode finger 15. This allows the main mode to be effectively reflected to the intersection region A side. In addition, the electric resistance of the IDT electrode 9C can be reduced.

Furthermore, in this modification, as in the first example embodiment, the transverse mode can be reduced or prevented, and the acoustic wave energy leakage can be reduced or prevented.

The configurations of the first to third modifications of the first example embodiment can also be used in other configurations of example embodiments of the present invention. For example, at least a first busbar of a pair of busbars of an IDT electrode may be provided with a plurality of apertures, as with those in the first modification. Alternatively, each busbar of the IDT electrode does not have to be provided with a plurality of apertures, and the IDT electrode does not have to include a plurality of offset electrodes.

Referring back to FIG. 2, examples of materials for each member of the piezoelectric substrate 2 will be described below.

Examples of the material that can be used for the support substrate 4 include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, semiconductors such as silicon, and materials mainly including any of the above materials. The spinel includes, for example, an aluminum compound including oxygen and one or more of Mg, Fe, Zn, Mn, or the like. Examples of the spinel include MgAl₂O₄, FeAl₂O₄, ZnAl₂O₄, or MnAl₂O₄. High-resistivity silicon, for example, is preferably used for the support substrate 4. The volume resistivity of the material for the support substrate 4 is, for example, preferably greater than or equal to about 1000 Ω·cm. In the first example embodiment, for example, high-resistivity silicon is used as the material for the support substrate 4.

The first layer 5a of the intermediate layer 5 is a high acoustic velocity film. The high acoustic velocity film is a film with a relatively high acoustic velocity. More specifically, the acoustic velocity of bulk waves propagating through the high acoustic velocity film is higher than the acoustic velocity of acoustic waves propagating through the piezoelectric layer 6. Examples of the material that can be used for the first layer 5a as the high acoustic velocity film include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, semiconductors such as silicon, and materials mainly including any of the above materials. The spinel above includes, for example, an aluminum compound including oxygen and one or more of Mg, Fe, Zn, Mn, or the like. Examples of the spinel include MgAl₂O₄, FeAl₂O₄, ZnAl₂O₄, or MnAl₂O₄. In the first example embodiment, for example, silicon nitride is used as the material for the first layer 5a.

The second layer 5b of the intermediate layer 5 is a low acoustic velocity film. The low acoustic velocity film is a film with a relatively low acoustic velocity. More specifically, the acoustic velocity of bulk waves propagating through the low acoustic velocity film is lower than the acoustic velocity of bulk waves propagating through the piezoelectric layer 6. Examples of the material that can be used for the second layer 5b as the low acoustic velocity film include dielectrics such as glass, silicon oxide, silicon oxynitride, lithium oxide, tantalum oxide, or a compound of silicon oxide with fluorine, carbon, or boron added, and materials mainly including any of the above materials. In the first example embodiment, silicon oxide is used as the material for the second layer 5b.

The piezoelectric layer 6 illustrated in FIG. 2 may be, for example, a piezoelectric single crystal substrate. The piezoelectric layer 6 may be formed, for example, by film deposition.

Examples of the material that can be used for the piezoelectric layer 6 include lithium tantalate, lithium niobate, zinc oxide, aluminum nitride, quartz, PZT (lead zirconate titanate), or the like. It is preferable to use, for example, lithium tantalate or lithium niobate as the material for the piezoelectric layer 6. In the first example embodiment, for example, lithium tantalate is used as the material for the piezoelectric layer 6.

In the piezoelectric layer 6 of the first example embodiment, the extending direction of the propagation axis is the X-propagation direction. However, example embodiments of the present invention are not limited thereto. The extending direction of the propagation axis may be, for example, the 90° X-propagation direction, or the direction perpendicular or substantially perpendicular to one of the directions in which the electrode fingers of the IDT electrode 9 extend.

In the first example embodiment, the first layer 5a as the high acoustic velocity film, the second layer 5b as the low acoustic velocity film, and the piezoelectric layer 6 are stacked in this order in the piezoelectric substrate 2. This allows the acoustic wave energy to be effectively confined to the piezoelectric layer 6 side.

The IDT electrode 9 and the reflectors 7A and 7B may be made of, for example, one or more metals including Ti, Mo, Ru, W, Al, Pt, Ir, Cu, Cr, or Sc. The IDT electrode 9 and the reflectors 7A and 7B may include a single-layer metal film or a multilayer metal film. In the first example embodiment, for example, Al is used as the material for the IDT electrode 9 and the reflectors 7A and 7B.

As used herein, the term “main component” refers to a component that accounts for more than 50% by weight. The main component material may be in any of a single-crystal state, a polycrystalline state, and an amorphous state, or in a mixed state thereof.

Hereinafter, the first mass addition film 8A, the second mass addition film 8B, the third mass addition film 8C, and other mass addition films may be collectively referred to simply as “mass addition films”. In the first example embodiment, the first mass addition film 8A, the second mass addition film 8B, and the third mass addition film 8C are provided directly on the piezoelectric layer 6 and on the first electrode fingers 15, on the second electrode fingers 16, or on the first floating electrodes 11. Therefore, in the portion where the mass addition film is stacked with the IDT electrode 9, the piezoelectric layer 6, the IDT electrode 9, and the mass addition film are stacked in this order. In the portion where the mass addition film is stacked with the IDT electrode 9, the piezoelectric layer 6, the mass addition film, and the IDT electrode 9 may also be stacked in this order. In other words, the mass addition film may be provided between the piezoelectric layer 6 and the IDT electrode 9.

The dielectric film 19 illustrated in FIG. 2 is provided on the first mass addition film 8A, the second mass addition film 8B, and the third mass addition film 8C. The first mass addition film 8A, the second mass addition film 8B, and the third mass addition film 8C may be made of an appropriate dielectric.

However, the first mass addition film 8A, the second mass addition film 8B, and the third mass addition film 8C may be provided on the dielectric film 19. In this case, the first mass addition film 8A, the second mass addition film 8B, and the third mass addition film 8C may be made of an appropriate metal or dielectric. It is preferable that the first mass addition film 8A, the second mass addition film 8B, and the third mass addition film 8C are made of the same material as that of the low acoustic velocity film.

In the first example embodiment, a plurality of floating electrodes are not provided on the second busbar 14 side. However, a plurality of floating electrodes may be provided on both of the first busbar 13 side and the second busbar 14 side. This example will be described in a second example embodiment of the present invention.

FIG. 18 is a schematic enlarged plan view illustrating the vicinity of a first busbar and a second busbar of an IDT electrode in the second example embodiment.

The present example embodiment differs from the first example embodiment in that an IDT electrode 29 includes a plurality of second floating electrodes 22. The present example embodiment also differs from the first example embodiment in that a plurality of apertures are not provided in a second busbar 14C. The second example embodiment also differs from the first example embodiment in that a fourth mass addition film 28D is provided. Otherwise, an acoustic wave device 20 of the present example embodiment has the same or substantially the same configuration as that of the acoustic wave device 10 of the first example embodiment. Hereinafter, the first floating electrodes 11 and the second floating electrodes 22 may be simply referred to as “floating electrodes”.

The plurality of second floating electrodes 22 are located between a second edge region H2 and the second busbar 14C. The plurality of second floating electrodes 22 are not connected to a first busbar 13, the second busbar 14C, a plurality of first electrode fingers 15, or a plurality of second electrode fingers 16. The plurality of second floating electrodes 22 and the plurality of second electrode fingers 16 are alternately arranged. A second floating electrode formation region U2 is located between the second edge region H2 and the second busbar 14C, and is the region where the plurality of second floating electrodes 22 are provided.

More specifically, the second floating electrode formation region U2 is a band-shaped region where the plurality of second floating electrodes 22 and the plurality of second electrode fingers 16 are alternately arranged. The second floating electrode formation region U2 includes all portions in the thickness direction of the acoustic wave device 20.

The fourth mass addition film 28D is provided in the second floating electrode formation region U2. Accordingly, a low acoustic velocity region is provided in the second floating electrode formation region U2. Specifically, the fourth mass addition film 28D has a band shape. The fourth mass addition film 28D is provided continuously over the plurality of second floating electrodes 22 and the plurality of second electrode fingers 16. Therefore, the fourth mass addition film 28D is also provided in the portions between the second floating electrodes 22 and the second electrode fingers 16 on the piezoelectric layer 6.

As with the first mass addition film 8A, the second mass addition film 8B, and the third mass addition film 8C, it is preferable to use the same material as the low acoustic velocity film described above for the material of the fourth mass addition film 28D.

The plurality of second floating electrodes 22 have a linear shape in plan view. The plurality of second floating electrodes 22 may have a curved shape in plan view, for example.

The plurality of first electrode fingers 15 each include a tip end portion facing one end portion of one of the plurality of second floating electrodes 22 across a gap. The region where the gap between the plurality of first electrode fingers 15 and the plurality of second floating electrodes 22 is located is a third gap region G3. The other end portions of the plurality of second floating electrodes 22 face the second busbar 14C across a gap. The region where the gap between the plurality of second floating electrodes 22 and the second busbar 14C is located is a fourth gap region G4.

The end portions of the plurality of second floating electrodes 22 on the second busbar 14C side are defined as the tip end portions of the plurality of second floating electrodes 22. The tip end portions of the plurality of second floating electrodes 22 each include a tip end. A virtual line connecting the tip ends of the plurality of second floating electrodes 22 is a fourth envelope E4. In this case, a region between the fourth envelope E4 and the second busbar 14C is the fourth gap region G4.

An extending direction of the fourth envelope E4 is orthogonal or substantially orthogonal to the extending direction of the plurality of second floating electrodes 22. Similarly, the extending direction of the second envelope E2 is orthogonal or substantially orthogonal to the extending direction of the plurality of second floating electrodes 22.

When the dimension of the third gap region G3 in the direction normal to the fourth envelope E4 is the width of the third gap region G3, the width of the third gap region G3 is less than about 1λ, for example, in the present example embodiment. When the dimension of the fourth gap region G4 in the direction normal to the fourth envelope E4 is the width of the fourth gap region G4, the width of the fourth gap region G4 is less than about 1λ, for example in the present example embodiment. However, the widths of the third gap region G3 and the fourth gap region G4 are not limited to the above.

In the present example embodiment, acoustic wave energy leakage can be effectively reduced or prevented on both the first busbar 13 side and the second busbar 14C side. In addition, a transverse mode can be reduced or prevented, as in the first example embodiment.

In the acoustic wave device 20, each mass addition film has a band shape in plan view. However, the present invention is not limited thereto. Hereinafter, first to third modifications of the second example embodiment will be described, each of which differs from the second example embodiment only in the shape or arrangement of any of the mass addition films. As in the second example embodiment, a transverse mode can be reduced or prevented, and acoustic wave energy leakage can be reduced or prevented in the first to third modifications.

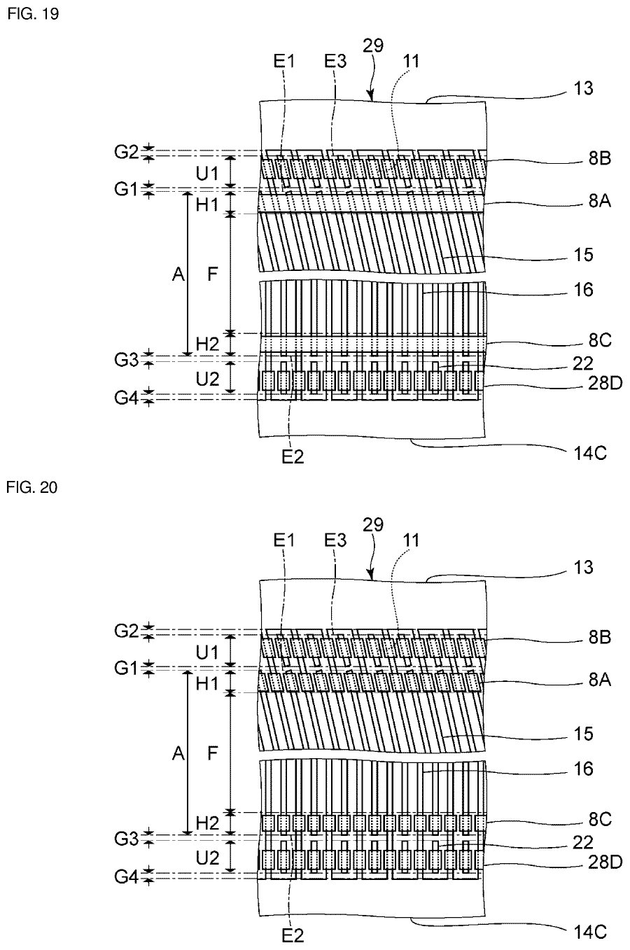

In the first modification illustrated in FIG. 19, a plurality of second mass addition films 8B are provided in the first floating electrode formation region U1. The plurality of second mass addition films 8B each have an individual piece shape. Specifically, the second mass addition film 8B is provided on each first electrode finger 15 and each second electrode finger 16. More specifically, each second mass addition film 8B is provided across one electrode finger and the piezoelectric layer 6. Each second mass addition film 8B is in contact with only one of two adjacent electrode fingers.

Similarly, a plurality of fourth mass addition films 28D are provided in the second floating electrode formation region U2. Each fourth mass addition film 28D is provided over one electrode finger and the piezoelectric layer 6. Each fourth mass addition film 28D is in contact with only one of two adjacent electrode fingers. The plurality of second mass addition films 8B and the plurality of fourth mass addition films 28D may each be provided only on one electrode finger.

In this modification, the plurality of second mass addition films 8B and the plurality of fourth mass addition films 28D can be made of an appropriate metal or dielectric.

On the other hand, as in the second example embodiment, one first mass addition film 8A is provided in the first edge region H1. One third mass addition film 8C is provided in the second edge region H2. The first mass addition film 8A and the third mass addition film 8C have a band shape in plan view. In this modification, low acoustic velocity regions are also provided in the first edge region H1, the first floating electrode formation region U1, the second edge region H2, and the second floating electrode formation region U2.

In the second modification illustrated in FIG. 20, a plurality of first mass addition films 8A are provided in the first edge region H1. The plurality of first mass addition films 8A each have an individual piece shape. Specifically, the first mass addition film 8A is provided on each first electrode finger 15 and each second electrode finger 16. More specifically, each first mass addition film 8A is provided across one electrode finger and the piezoelectric layer 6. Each first mass addition film 8A is in contact with only one of two adjacent electrode fingers.

Similarly, a plurality of third mass addition films 8C are provided in the second edge region H2. Each third mass addition film 8C is provided across one electrode finger and the piezoelectric layer 6. Each third mass addition film 8C is in contact with only one of two adjacent electrode fingers. The plurality of first mass addition films 8A and the plurality of third mass addition films 8C may each be provided only on one electrode finger.

In this modification, the plurality of first mass addition films 8A and the plurality of third mass addition films 8C can be made of an appropriate metal or dielectric, for example.

In addition, as in the first modification, a plurality of second mass addition films 8B are provided in the first floating electrode formation region U1. A plurality of fourth mass addition films 28D are provided in the second floating electrode formation region U2. Each second mass addition film 8B and each fourth mass addition film 28D has an individual piece shape. In this modification, low acoustic velocity regions are also provided in the first edge region H1, the first floating electrode formation region U1, the second edge region H2, and the second floating electrode formation region U2.

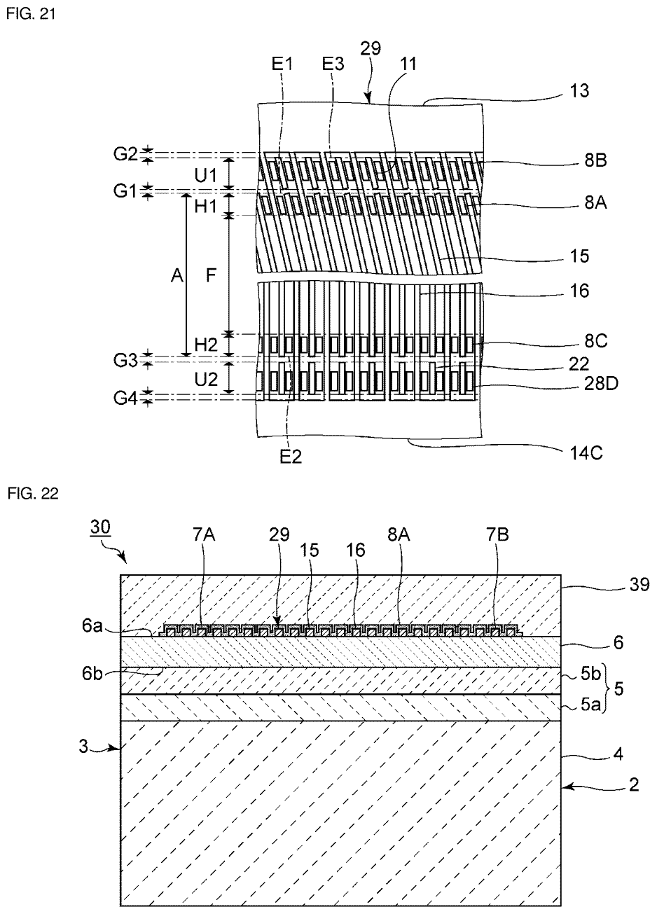

In the third modification illustrated in FIG. 21, a plurality of first mass addition films 8A are provided in the first edge region H1. Each first mass addition film 8A has an individual piece shape. Specifically, the plurality of first mass addition films 8A are provided in portions between the electrode fingers on the piezoelectric layer 6. Each first mass addition film 8A is not in contact with the electrode fingers.

A plurality of second mass addition films 8B are also provided in the first floating electrode formation region U1. Each second mass addition film 8B is provided in a portion between the first floating electrode 11 and the first electrode finger 15 on the piezoelectric layer 6. A plurality of third mass addition films 8C are also provided in the second edge region H2. Each third mass addition film 8C is provided in a portion between the electrode fingers on the piezoelectric layer 6. Similarly, a plurality of fourth mass addition films 28D are also provided in the second floating electrode formation region U2. Each fourth mass addition film 28D is provided in a portion between the second floating electrode 22 and the second electrode finger 16 on the piezoelectric layer 6. Each second mass addition film 8B, each third mass addition film 8C, and each fourth mass addition film 28D is not in contact with the electrode fingers or floating electrodes.

In this modification, the plurality of first mass addition films 8A, the plurality of second mass addition films 8B, the plurality of third mass addition films 8C, and the plurality of fourth mass addition films 28D can be made of an appropriate metal or dielectric, for example. Each first mass addition film 8A and each third mass addition film 8C may be in contact with both of two adjacent electrode fingers. Each second mass addition film 8B and each fourth mass addition film 28D may be in contact with both of adjacent electrode fingers and floating electrodes. In these cases, the plurality of first mass addition films 8A, the plurality of second mass addition films 8B, the plurality of third mass addition films 8C, and the plurality of fourth mass addition films 28D can be made of an appropriate dielectric.

In this modification, low acoustic velocity regions are also provided in the first edge region H1, the first floating electrode formation region U1, the second edge region H2, and the second floating electrode formation region U2.

Although some examples have been provided in the first to third modifications, combinations of the arrangement of the mass addition films may be other than those illustrated in the first to third modifications.

Although omitted in FIG. 18, the acoustic wave device 20 includes a dielectric film 19 described with reference to FIG. 2. The dielectric film 19 has a thickness smaller than that of the IDT electrode 29. However, the IDT electrode 29 may be embedded in a protective film. This example will be described in a third example embodiment of the present invention.

FIG. 22 is a schematic elevational cross-sectional view illustrating a portion passing through a first edge region of an acoustic wave device according to the third example embodiment.

The present example embodiment differs from the second example embodiment in that the IDT electrode 29 includes a protective film 39 instead of the dielectric film 19 described with reference to FIG. 2. Otherwise, an acoustic wave device 30 of the present example embodiment has the same or substantially the same configuration as that of the acoustic wave device 20 of the second example embodiment.

Specifically, a protective film 39 is provided on the piezoelectric layer 6 so as to cover the IDT electrode 29. The protective film 39 has a thickness greater than that of the IDT electrode 29. The IDT electrode 29 is embedded in the protective film 39. This makes the IDT electrode 29 less susceptible to damage. In addition, as in the second example embodiment, a transverse mode can be reduced or prevented, and acoustic wave energy leakage can be reduced or prevented in the present example embodiment.

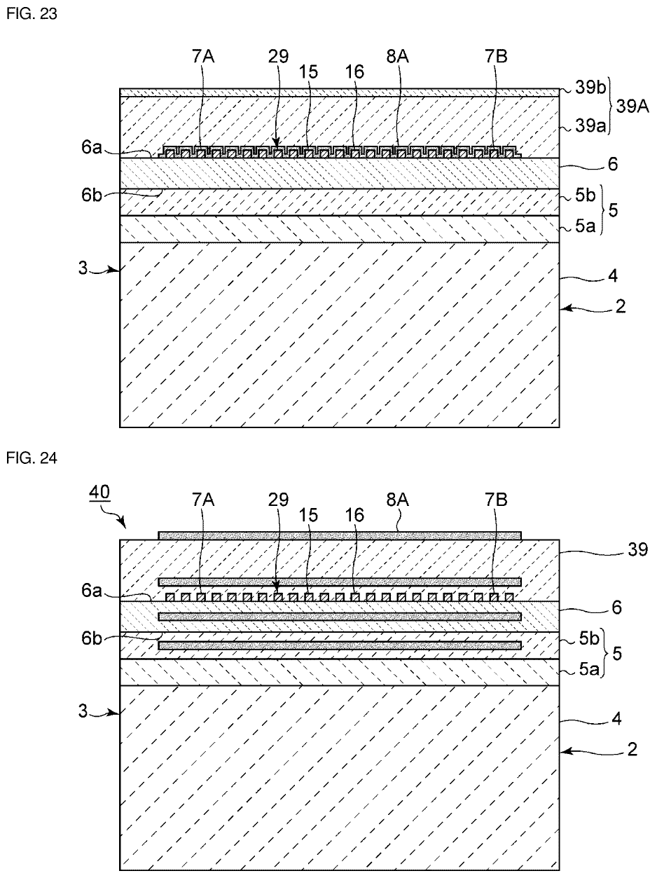

The protective film 39 is a single-layer film. However, the protective film 39 may be a multilayer body. For example, in a modification of the third example embodiment illustrated in FIG. 23, a protective film 39A includes a first protective layer 39a and a second protective layer 39b. The IDT electrode 29 is embedded in the first protective layer 39a. The second protective layer 39b is provided on the first protective layer 39a. This allows the protective film 39A to achieve a plurality of advantageous effects.

Specifically, in this modification, for example, silicon oxide is used as the material for the first protective layer 39a. This makes it possible to reduce the absolute value of a temperature coefficient of frequency (TCF) of the acoustic wave device. Accordingly, temperature characteristics of the acoustic wave device can be improved. Silicon nitride, for example, is used for the second protective layer 39b. This makes it possible to improve moisture resistance of the acoustic wave device. However, the materials for the first protective layer 39a and the second protective layer 39b are not limited to those described above. The protective film 39A may also be a multilayer body including three or more layers.

In this modification, as in the third example embodiment, a transverse mode can be reduced or prevented, and acoustic wave energy leakage can be reduced or prevented.

In the first to third example embodiments and the modifications thereof, each mass addition film is provided directly on the piezoelectric layer or the IDT electrode. The arrangement of each mass addition film is not limited to the above. This example will be described in a fourth example embodiment of the present invention.

FIG. 24 is a schematic elevational cross-sectional view illustrating a portion passing through a first edge region of an acoustic wave device according to the fourth example embodiment.

The present example embodiment differs from the third example embodiment in the arrangement of each mass addition film. Otherwise, an acoustic wave device 40 of the present example embodiment has the same or substantially the same configuration as that of the acoustic wave device 30 of the third example embodiment.

In the acoustic wave device 40, a first mass addition film 8A is provided in a piezoelectric substrate 2. Specifically, one first mass addition film 8A is provided in a piezoelectric layer 6 and one in a second layer 5b of an intermediate layer 5. In addition, one first mass addition film 8A is provided in a protective film 39 and one on the protective film 39.

Similarly, one second mass addition film, one third mass addition film, and one fourth mass addition film are provided in the piezoelectric layer 6, in the second layer 5b of the intermediate layer 5, in the protective film 39, and on the protective film 39. In the present example embodiment, as in the third example embodiment, low acoustic velocity regions are also formed in the first edge region, the first floating electrode formation region, the second edge region, and the second floating electrode formation region. This makes it possible to reduce or prevent a transverse mode and reduce acoustic wave energy leakage in the acoustic wave device 40.

In the present example embodiment, each mass addition film has a band shape in plan view. However, at least one of the first mass addition film 8A, the second mass addition film, the third mass addition film, and the fourth mass addition film may be arranged in the same or substantially the same manner as in the first to third modifications of the second example embodiment illustrated in FIGS. 19 to 21. Alternatively, combinations of the arrangement of the mass addition films may be other than those of the first to third modifications.

It is sufficient that the first mass addition film 8A is provided at least in the piezoelectric substrate 2, on the piezoelectric layer 6, on the electrode fingers, in the protective film 39, or on the protective film 39. The same applies to the third mass addition film. It is sufficient that the second mass addition film is provided at least in the piezoelectric substrate 2, on the piezoelectric layer 6, on the first floating electrode, on the first electrode fingers 15, in the protective film 39, or on the protective film 39. It is sufficient that the fourth mass addition film is provided at least in the piezoelectric substrate 2, on the piezoelectric layer 6, on the second floating electrode, on the second electrode fingers 16, in the protective film 39, or on the protective film 39.

In the first to fourth example embodiments and the modifications thereof, the low acoustic velocity region is provided by including the mass addition films. However, the low acoustic velocity region may also be provided by widening the width of the electrode fingers or floating electrodes. This example will be described in a fifth example embodiment of the present invention.

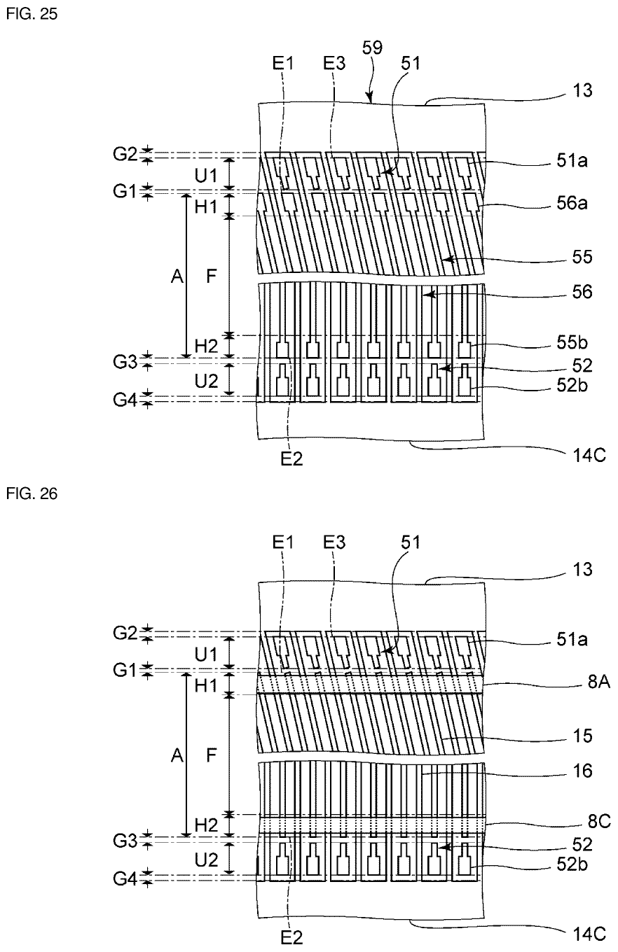

FIG. 25 is a schematic enlarged plan view illustrating the vicinity of a first busbar and a second busbar of an IDT electrode according to the fifth example embodiment.

The present example embodiment differs from the second example embodiment in that no mass addition films are provided and that electrode fingers and floating electrodes of an IDT electrode 59 include wide portions. The width of the electrode finger in the wide portion is wider than the width of the electrode finger in the central region F. The width of the floating electrode in the wide portion is wider than the width of the floating electrode in a portion other than the wide portion. Otherwise, an acoustic wave device of the present example embodiment has the same or substantially the same configuration as that of the acoustic wave device 20 of the second example embodiment.

Specifically, in the first edge region H1, a plurality of second electrode fingers 56 include first wide portions 56a that are wider than the width in the central region F. Accordingly, a low acoustic velocity region is provided in the first edge region H1. In the present example embodiment, a plurality of first electrode fingers 55 do not include first wide portions in the first edge region H1. However, the plurality of first electrode fingers 55 may include first wide portions in the first edge region H1.

In addition, in the first floating electrode formation region U1, a plurality of first floating electrodes 51 include second wide portions 51a that are wider than the width in other portions. Accordingly, a low acoustic velocity region is provided in the first floating electrode formation region U1. In the present example embodiment, the plurality of first electrode fingers 55 do not include second wide portions in the first floating electrode formation region U1. However, the plurality of first electrode fingers 55 may include second wide portions in the first floating electrode formation region U1.

On the other hand, in the second edge region H2, the plurality of first electrode fingers 55 include third wide portions 55b that are wider than the width in the central region F. Accordingly, a low acoustic velocity region is provided in the second edge region H2. In the present example embodiment, the plurality of second electrode fingers 56 do not include the third wide portions in the second edge region H2. However, the plurality of second electrode fingers 56 may include the third wide portions in the second edge region H2.

Furthermore, in the second floating electrode formation region U2, a plurality of second floating electrodes 52 include fourth wide portions 52b that are wider than the width in other portions. Accordingly, a low acoustic velocity region is provided in the second floating electrode formation region U2. In the present example embodiment, the plurality of second electrode fingers 56 do not include the fourth wide portions in the second floating electrode formation region U2. However, the plurality of second electrode fingers 56 may include the fourth wide portions in the second floating electrode formation region U2.

The present example embodiment has the following configuration. 1) In the first edge region H1, the plurality of first electrode fingers 55, the plurality of second electrode fingers 56, or both include the first wide portions that are wider than the width in the central region F. 2) The acoustic wave device includes at least one of the following configurations in the first floating electrode formation region U1: a configuration in which the plurality of first electrode fingers 55 include the second wide portions that are wider than the width in the central region F; and a configuration in which the plurality of first floating electrodes 51 include the second wide portions 51a that are wider than the width in other portions. Accordingly, the low acoustic velocity regions are provided in the first edge region H1 and the first floating electrode formation region U1. In this case, as in the first and second example embodiments and the like, a transverse mode can be reduced or prevented, and acoustic wave energy leakage can be reduced or prevented.

As in the present example embodiment, the acoustic wave device preferably has the following configuration. 3) In the second edge region H2, the plurality of first electrode fingers 55, the plurality of second electrode fingers 56, or both include the third wide portions that are wider than the width in the central region F. 4) The acoustic wave device includes at least one of the following configurations in the second floating electrode formation region U2: a configuration in which the plurality of second electrode fingers 56 include the fourth wide portions that are wider than the width in the central region F; and a configuration in which the plurality of second floating electrodes 52 include the fourth wide portions 52b that are wider than the other portions. With the acoustic wave device having the configuration 3) or 4) above, a transverse mode can be effectively reduced or prevented, and acoustic wave energy leakage can be effectively reduced or prevented.

However, mass addition films may also be provided even when the electrode fingers or floating electrodes have wide portions. This example will be described in first and second modifications of the fifth example embodiment, which differ from the fifth example embodiment only in including mass addition films and the arrangement of the wide portions. As in the fifth example embodiment, a transverse mode can be reduced or prevented, and acoustic wave energy leakage can be reduced or prevented in the first and second modifications.

In the first modification illustrated in FIG. 26, a first mass addition film 8A is provided in a first edge region H1. A third mass addition film 8C is provided in a second edge region H2. Meanwhile, a first floating electrode formation region U1 and a second floating electrode formation region U2 are configured in the same or substantially the same manner as in the fifth example embodiment.

It is sufficient that the acoustic wave device have the configuration 2) above in the first floating electrode formation region U1. That is, it is sufficient that, in this region, the acoustic wave device have at least one of the following configurations: a configuration in which the plurality of first electrode fingers 55 include second wide portions that are wider than the width in the central region F, and a configuration in which the plurality of first floating electrodes 51 include second wide portions 51a that are wider than the other portions. It is sufficient that the acoustic wave device have the configuration 4) above in the second floating electrode formation region U2. That is, it is sufficient that, in this region, the acoustic wave device includes at least one of the following configurations: a configuration in which the plurality of second electrode fingers 56 include fourth wide portions that are wider than the width in the central region F, and a configuration in which the plurality of second floating electrodes 52 include fourth wide portions 52b that are wider than the other portions.

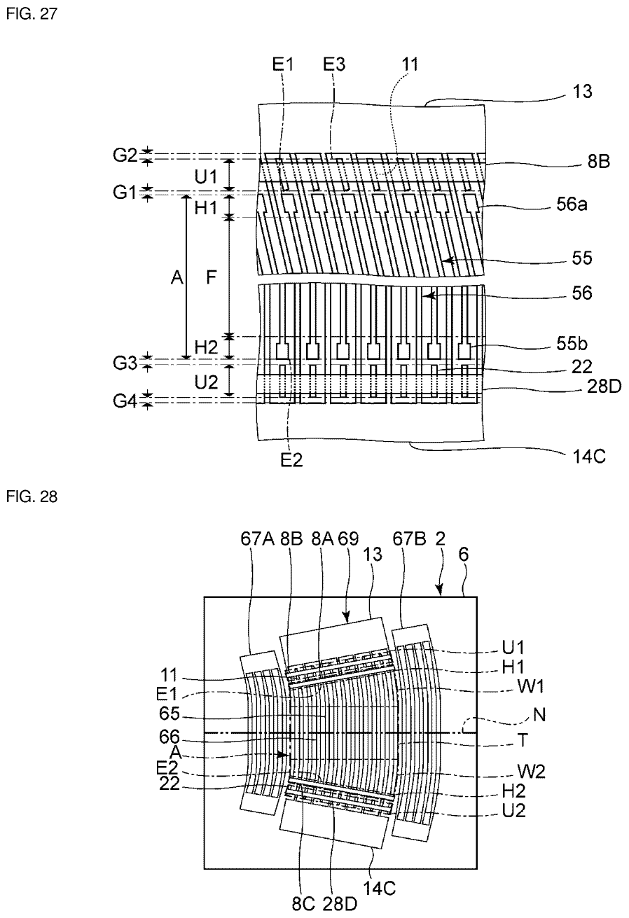

In the second modification illustrated in FIG. 27, a second mass addition film 8B is provided in a first floating electrode formation region U1. A fourth mass addition film 28D is provided in a second floating electrode formation region U2. Meanwhile, a first edge region H1 and a second edge region H2 are configured in the same or substantially the same manner as in the fifth example embodiment.

It is sufficient that the acoustic wave device have the configuration 1) above in the first edge region H1. That is, it is sufficient that, in this region, the plurality of first electrode fingers 55, the plurality of second electrode fingers 56, or both include first wide portions that are wider than the width in the central region F. It is sufficient that the acoustic wave device have the configuration 3) above in the second edge region H2. That is, it is sufficient that, in this region, the plurality of first electrode fingers 55, the plurality of second electrode fingers 56, or both include third wide portions that are wider than the width in the central region F.

Alternatively, the electrode fingers or floating electrodes may include wide portions in the region where the mass addition film is provided. This may also cause a low acoustic velocity region to be provided.

In the IDT electrodes of the first to fifth example embodiments and the modifications thereof, the shape of the plurality of electrode fingers in plan view can be approximated to an arc. The shape of the plurality of electrode fingers in plan view may include an arc shape, for example. In this case, the shape of the plurality of electrode fingers in plan view includes a shape corresponding to each of the arcs in a plurality of concentric circles. Therefore, the centers of the circles including the arcs in the shapes of the plurality of electrode fingers coincide. This center is considered a fixed point.

As described above, in the first example embodiment, the portions with the same excitation angle θ_{C_prop} are arranged in a curved line. On the other hand, if the plurality of electrode fingers have an arc shape in plan view, the portions with the same excitation angle θ_{C_prop} are linearly arranged. Specifically, the portions with the same excitation angle θ_{C_prop} are arranged on a straight line passing through the fixed point and the intersection region.

Alternatively, the shape of the plurality of electrode fingers in plan view may include an elliptical arc, for example. In this case, the shape of the plurality of electrode fingers in plan view includes a shape corresponding to each elliptical arc in a plurality of ellipses with the same or substantially the same center of gravity. With the center of gravity considered as the fixed point, the portions with the same excitation angle θ_{C_prop} are arranged on a straight line passing through the fixed point and the intersection region.

It is preferable that the shape of the plurality of reflector electrode fingers of each reflector corresponds to the shape of the plurality of electrode fingers of the IDT electrode. Specifically, if the shape of the plurality of electrode fingers in plan view includes an arc shape, it is preferable that the shape of the plurality of reflector electrode fingers in plan view also include an arc shape. It is preferable that the centers of the circles including the arcs in the shapes of the plurality of electrode fingers and the plurality of reflector electrode fingers coincide. If the shape of the plurality of electrode fingers in plan view includes an elliptical arc shape, for example, it is preferable that the shape of the plurality of reflector electrode fingers in plan view also include an elliptical arc shape. It is preferable that the centers of gravity of the ellipses including the elliptical arcs in the shapes of the plurality of electrode fingers and the plurality of reflector electrode fingers coincide. This allows each reflector to effectively reflect acoustic waves to the IDT electrode side.

In example embodiments of the present invention, the shape of the plurality of electrode fingers in plan view may include both a curved portion and a linear portion. This example will be described in a sixth example embodiment of the present invention and a seventh example embodiment of the present invention.

FIG. 28 is a schematic plan view of an acoustic wave device according to the sixth example embodiment.

The present example embodiment differs from the second example embodiment in the shape of a plurality of electrode fingers of an IDT electrode 69. The shape of a plurality of reflector electrode fingers of a reflector 67A and a reflector 67B in plan view also corresponds to the shape of the plurality of electrode fingers in plan view. The present example embodiment also differs from the second example embodiment in that an extending direction of a first envelope E1 intersects with an extending direction of a second envelope E2. Otherwise, the acoustic wave device of the present example embodiment has the same or substantially the same configuration as that of the acoustic wave device 20 of the second example embodiment.

An intersection region A of the IDT electrode 69 includes a first curved region W1, a second curved region W2, and a linear region T. As described above, the curved regions are regions in which a plurality of first electrode fingers 65 and a plurality of second electrode fingers 66 each have a curved shape in plan view. The intersection region A may include three or more curved regions, for example.

On the other hand, the linear region T is a region in which the plurality of first electrode fingers 65 and the plurality of second electrode fingers 66 each have a linear shape in plan view. The first curved region W1, the second curved region W2, and the linear region T are arranged in the direction in which a first busbar 13 and a second busbar 14C face each other. More specifically, the first curved region W1 and the second curved region W2 face each other across the linear region T.

One edge of the first curved region W1 is the first envelope E1. The other edge of the first curved region W1 is the boundary between the first curved region W1 and the linear region T. One edge of the second curved region W2 is the second envelope E2. The other edge of the second curved region W2 is the boundary between the second curved region W2 and the linear region T.

In the IDT electrode 69, each electrode finger includes two inflection points. In this specification, each inflection point is a point where a curved portion and a linear portion are connected. The portion where the inflection points of the plurality of electrode fingers are aligned is the boundary between the curved region and the linear region.

A dash-dot-dot line N in FIG. 28 passes through the center of the intersection region A and extends parallel or substantially parallel to the direction in which the propagation axis extends. More specifically, the dash-dot-dot line N passes through the center of the linear region T. The first envelope E1 is inclined in the positive direction with respect to the extending direction of the propagation axis. The second envelope E2 is inclined in the negative direction with respect to the extending direction of the propagation axis.

In the present example embodiment, the excitation angle θ_{C_prop} is not uniform in each of the first curved region W1 and the second curved region W2. However, the resonant frequencies or anti-resonant frequencies match or substantially match throughout the first curved region W1 and the second curved region W2. Furthermore, the resonant frequencies or anti-resonant frequencies match or substantially match in the entire intersection region A. This allows for dispersion and reduction or prevention of unwanted out-of-band waves, such as Rayleigh waves, for example.

In the linear region T, the excitation angle θ_{C_prop} is constant. More specifically, the excitation angle θ_{C_prop} is 0° in the linear region T. In other words, in the present example embodiment, the extending direction of the plurality of electrode fingers is orthogonal or substantially orthogonal to the extending direction of the propagation axis in the entire or substantially the entire linear region T. Therefore, the linear region T is a stable region with respect to the propagation axis. With the intersection region A including the linear region T, the change in the propagation direction can be reduced or prevented in the entire or substantially the entire IDT electrode 69, thus stabilizing the propagation of acoustic waves. The excitation angle θ_{C_prop} in the linear region T does not necessarily have to be 0°.

In the present example embodiment, the first curved region W1 includes a first edge region H1. A first floating electrode formation region U1 is provided between the first edge region H1 and the first busbar 13. Furthermore, a first gap region is disposed between the first edge region H1 and the first floating electrode formation region U1. A second gap region is disposed between the first floating electrode formation region U1 and the first busbar 13.

On the other hand, the second curved region W2 includes a second edge region H2. A second floating electrode formation region U2 is provided between the second edge region H2 and the second busbar 14C. A third gap region is disposed between the second edge region H2 and the second floating electrode formation region U2. A fourth gap region is disposed between the second floating electrode formation region U2 and the second busbar 14C.

As in the second example embodiment, mass addition films are provided in the first edge region H1, the second edge region H2, the first floating electrode formation region U1, and the second floating electrode formation region U2. Accordingly, low acoustic velocity regions are provided in the first edge region H1, the second edge region H2, the first floating electrode formation region U1, and the second floating electrode formation region U2. This makes it possible to reduce or prevent a transverse mode and reduce or prevent acoustic wave energy leakage in the present example embodiment.

In the first to sixth example embodiments and the modifications thereof, the curves in the shape of the plurality of electrode fingers in plan view are smooth curves, for example. However, the curves in the shape of the plurality of electrode fingers in plan view may also be provided by connecting very small straight lines. The curves in the shape of the plurality of electrode fingers in plan view may also be provided by connecting a plurality of vertices with curves. Alternatively, the curves in the shape of the plurality of electrode fingers in plan view do not necessarily have to be smooth curves. This example will be described as a modification of the sixth example embodiment.

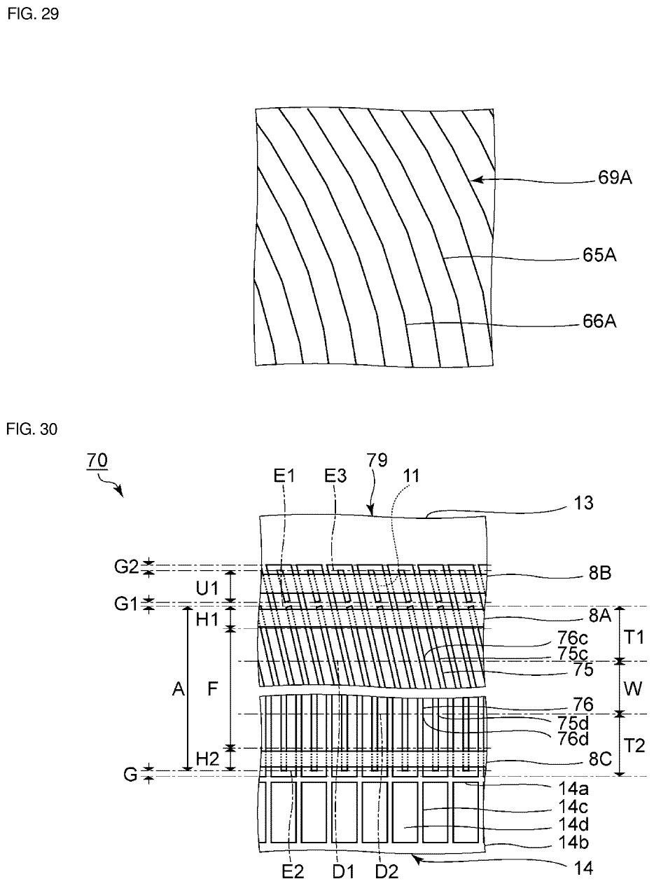

In an IDT electrode 69A of the modification illustrated in in an enlarged view in FIG. 29, the curve in the shape of each first electrode finger 65A in plan view is not smooth. Specifically, the shape of each first electrode finger 65A in plan view is provided by connecting straight lines. The straight lines in this shape are not very small. More specifically, the length of the straight lines in this shape is, for example, about several % of the total length of the first electrode finger 65A. However, in this shape, the angle between the connected straight lines is as large as, for example, greater than or equal to about 160° and less than about 180°. Therefore, the shape of each first electrode finger 65A in plan view is a shape that can be approximated to a curve. The same applies to a second electrode finger 66A.

In this modification, as in the sixth example embodiment, a transverse mode can be reduced or prevented, and acoustic wave energy leakage can be reduced or prevented.

FIG. 30 is a schematic enlarged plan view illustrating the vicinity of a first busbar and a second busbar of an IDT electrode in a seventh example embodiment of the present invention.

The present example embodiment differs from the first example embodiment in the shape of a plurality of electrode fingers of an IDT electrode 79 and the arrangement of curved regions. The shape of a plurality of reflector electrode fingers of each reflector in plan view also corresponds to the shape of the plurality of electrode fingers in plan view. Otherwise, an acoustic wave device 70 of the present example embodiment has the same or substantially the same configuration as that of the acoustic wave device 10 of the first example embodiment.

An intersection region A in the acoustic wave device 70 includes a curved region W, a first linear region T1, and a second linear region T2. The curved region W, the first linear region T1, and the second linear region T2 are arranged in the direction in which a first busbar 13 and a second busbar 14 face each other. More specifically, the first linear region T1 and the second linear region T2 face each other across the curved region W. The first linear region T1 includes a portion of a central region F and a first edge region H1 in the intersection region A. The second linear region T2 includes a portion of the central region F and a second edge region H2. The curved region W is included in the central region F.

One edge of the curved region W is the boundary between the curved region W and the first linear region T1. This edge is a first intersection line D1. The first intersection line D1 is a virtual line extending parallel or substantially parallel to a first envelope E1 and passing through the central region F in the intersection region A.

The other edge of the curved region W is the boundary between the curved region W and the second linear region T2. This edge is a second intersection line D2. The second intersection line D2 is a virtual line extending parallel or substantially parallel to a second envelope E2 and passing through the central region F.

A portion of each first electrode finger 75 that intersects with the first intersection line D1 is a first intersection portion 75c. A portion of each second electrode finger 76 that intersects with the first intersection line D1 is a second intersection portion 76c. On the other hand, a portion of each first electrode finger 75 that intersects with the second intersection line D2 is a first intersection portion 75d. A portion of each second electrode finger 76 that intersects with the second intersection line D2 is a second intersection portion 76d.

The first intersection portion 75c is a portion located in the curved region W, and is a portion within a range of, for example, about 1λ from the first intersection line D1 in the direction in which the first electrode finger 75 extends. Similarly, the second intersection portion 76c is a portion located in the curved region W, and is a portion within a range of, for example, about 1λ from the first intersection line D1 in the direction in which the second electrode finger 76 extends. On the other hand, the first intersection portion 75d is a portion located in the curved region W, and is a portion within a range of, for example, about 1λ from the second intersection line D2 in the direction in which the first electrode finger 75 extends. The second intersection portion 76d is a portion located in the curved region W, and is a portion within a range of, for example, about 1λ from the second intersection line D2 in the direction in which the second electrode finger 76 extends.

In the curved region W, the excitation angle θ_{C_prop} is not uniform. However, the resonant frequencies or anti-resonant frequencies match or substantially match throughout the entire curved region W. Furthermore, the resonant frequencies or anti-resonant frequencies also match or substantially match throughout the entire intersection region A. This allows for dispersion and reduction or prevention of unwanted out-of-band waves, such as Rayleigh waves, for example.

In the present example embodiment, the curvature of each of the first electrode fingers 75 and second electrode fingers 76 is not constant in the curved region W. Furthermore, in the present example embodiment, the curvature differs between the first intersection portions 75c and the second intersection portions 76c of all of the first electrode fingers 75 and all of the second electrode fingers 76. In this case, in the curved region W, all of the electrode fingers of the IDT electrode 79 have different curved shapes in plan view. This allows for more reliable and effective reduction or prevention of unwanted waves, as in the first example embodiment.

In addition, in the present example embodiment, the curvature differs between the first intersection portions 75d and the second intersection portions 76d of all of the first electrode fingers 75 and all of the second electrode fingers 76. In this case, again, in the curved region W, all of the electrode fingers of the IDT electrode 79 have different curved shapes in plan view. This configuration also allows for more reliable and effective reduction or prevention of unwanted waves.

However, it is sufficient that the curvature differs between the first intersection portions 75c and the second intersection portions 76c of at least one pair of electrode fingers among the plurality of first electrode fingers 75 and the plurality of second electrode fingers 76. Alternatively, it is sufficient that the curvature differs between the first intersection portions 75d and the second intersection portions 76d of at least one pair of electrode fingers among the plurality of first electrode fingers 75 and the plurality of second electrode fingers 76.

In other words, it is sufficient that, when the first intersection line D1 or the second intersection line D2 is an intersection line, the first intersection portion and the second intersection portion based on that intersection line have the above configuration. Specifically, a portion of each first electrode finger 75 that intersects with the intersection line is the first intersection portion. A portion of each second electrode finger 76 that intersects with the intersection line is the second intersection portion. Furthermore, it is sufficient that, in the curved region W, the curvature differs between the first intersection portion and the second intersection portion of at least one pair of electrode fingers among the plurality of first electrode fingers 75 and the plurality of second electrode fingers 76.

In the curved region W of the acoustic wave device 70, the shapes of all of the electrode fingers in plan view can each be approximated to an arc and have different curved shapes. Therefore, the relationship illustrated in FIG. 14 is satisfied in the curved region W. More specifically, in the curved region W, when the shapes of all of the first electrode fingers 75 and all of the second electrode fingers 76 in plan view are approximated to arcs, the centers of circles including these arcs are located at different positions.

As in the first example embodiment, a mass addition film is provided in each of the first edge region H1, the second edge region H2, and the first floating electrode formation region U1. Accordingly, low acoustic velocity regions are provided in the first edge region H1, the second edge region H2, and the first floating electrode formation region U1. This makes it possible to reduce or prevent a transverse mode and reduce or prevent acoustic wave energy leakage in the present example embodiment.

As in the fifth example embodiment, a low acoustic velocity region may be provided by including a wide portion. Alternatively, as in each of the modifications of the fifth example embodiment, a low acoustic velocity region may be provided by including a mass addition film and a wide portion.

In the present example embodiment, the portion where the excitation angle θ_{C_prop} is 0° is the portion on the second envelope E2. In all portions of the intersection region A, the excitation angle θ_{C_prop} is greater than or equal to 0°. However, the intersection region A may include portions where the excitation angle θ_{C_prop} is less than 0°.

In portions of the IDT electrode 79 where the excitation angle θ_{C_prop} is the same or substantially the same, both of the electrode finger pitch and the duty ratio are constant. However, the present invention is not limited thereto. However, it is preferable that at least one of the electrode finger pitch and the duty ratio is constant in the portions with the same or substantially the same excitation angle θ_{C_prop}. This makes it possible to more reliably improve resonance characteristics of the acoustic wave device 70.

As described above, in the intersection region A, the acoustic wave excitation direction in any portion of any of the plurality of electrode fingers is one of the first to third directions. In the present example embodiment, the excitation direction is the first direction. Specifically, the first direction as the acoustic wave excitation direction in any portion of any of the electrode fingers is a direction perpendicular or substantially perpendicular to the extending direction of the electrode finger. The excitation direction may be the second direction or the third direction.

In the IDT electrode 79, the extending direction of the first envelope E1 and the extending direction of the second envelope E2 are parallel or substantially parallel to each other. However, as in the sixth example embodiment or the like, for example, the extending direction of the first envelope E1 and the extending direction of the second envelope E2 may intersect with each other.

Furthermore, in example embodiments of the present invention, the plurality of electrode fingers and the plurality of reflector electrode fingers may each have a shape that is bent at a plurality of joints. This example will be described in an eighth example embodiment of the present invention.

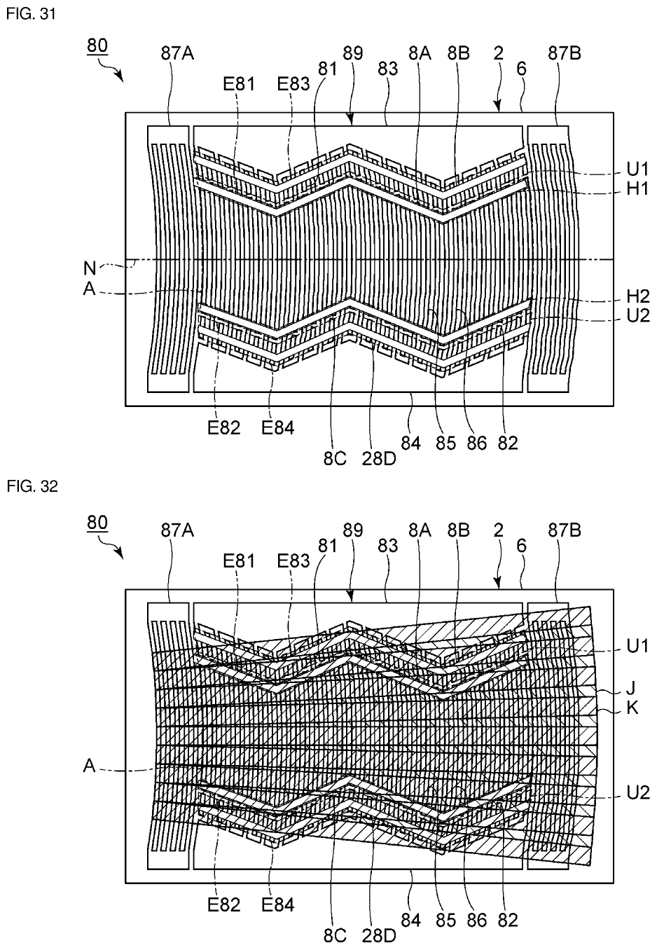

FIG. 31 is a schematic plan view of an acoustic wave device according to the eighth example embodiment.

The present example embodiment differs from the second example embodiment in the shape of a plurality of electrode fingers of an IDT electrode 89. The shape of a plurality of reflector electrode fingers of reflectors 87A and 87B in plan view also corresponds to the shape of the plurality of electrode fingers in plan view. The present example embodiment also differs from the second example embodiment in the shapes of a first busbar 83 and a second busbar 84, and the shapes of a first envelope E81, a second envelope E82, a third envelope E83, and a fourth envelope E84. Otherwise, an acoustic wave device 80 of the present example embodiment has the same or substantially the same configuration as that of the acoustic wave device 20 of the second example embodiment.

In the IDT electrode 89, the plurality of first electrode fingers 85 and the plurality of second electrode fingers 86 each have a shape in plan view that is bent at a plurality of joints. More specifically, the plurality of first electrode fingers 85 and the plurality of second electrode fingers 86 each have a shape in plan view in which straight lines are connected at each joint. A plurality of first floating electrodes 81 and a plurality of second floating electrodes 82 each have a shape in plan view that is bent at one joint or a plurality of joints.

In the present example embodiment, each electrode finger and each floating electrode is bent so as to be convex to the reflector 87B side. The shape of each electrode finger and each floating electrode in plan view can be approximated to an arc, an elliptical arc, or a parabola, for example.

FIG. 32 is a schematic plan view illustrating parallel regions and non-parallel regions in the eighth example embodiment. In FIG. 32, each region is indicated by hatching. The parallel regions and extended regions of the parallel regions to be described later are denoted by the same hatching and reference numeral. The non-parallel regions and extended regions of the non-parallel regions to be described later are denoted by the same hatching and reference numeral.

An intersection region A includes a plurality of parallel regions J and a plurality of non-parallel regions K. Similarly, a first floating electrode formation region U1 and a second floating electrode formation region U2 each also include one or more parallel regions J and one or more non-parallel regions K. Specifically, the parallel region J is a region where the plurality of first electrode fingers 85 and the plurality of second electrode fingers 86 extend parallel or substantially parallel to each other. The parallel region J is also a region where the plurality of first floating electrodes 81 and the plurality of second floating electrodes 82 extend parallel or substantially parallel to each other. The non-parallel region K is a region where the extending directions of the plurality of first electrode fingers 85 and the plurality of second electrode fingers 86 intersect with each other. The non-parallel region K is also a region where the extending directions of the plurality of first floating electrodes 81 and the plurality of second floating electrodes 82 intersect with each other.

It is sufficient that the intersection region A include at least two parallel regions J and at least one non-parallel region K. The first floating electrode formation region U1 and the second floating electrode formation region U2 do not necessarily have to include both of the parallel region J and the non-parallel region K.

The parallel regions J and the non-parallel regions K are alternately arranged. The plurality of first electrode fingers 85 and the plurality of second electrode fingers 86 each extend linearly in the parallel regions J and the non-parallel regions K, and are bent at the boundaries between the parallel regions J and the non-parallel regions K. In the present example embodiment, the parallel regions J and the non-parallel regions K are alternately arranged throughout the entire or substantially the entire intersection region A. It is sufficient that the parallel regions J and the non-parallel regions K are alternately arranged in at least a portion of the intersection region A.

The plurality of electrode fingers extend in different directions among the plurality of parallel regions J. Therefore, the acoustic wave excitation direction and excitation angle θ_{C_prop} are not uniform in the intersection region A. Furthermore, in the present example embodiment, the resonant frequencies or anti-resonant frequencies match or substantially match throughout the entire or substantially the entire intersection region A. This allows for dispersion and reduction or prevention of unwanted out-of-band waves, such as Rayleigh waves.

In addition, some of the plurality of floating electrodes and some of the plurality of electrode fingers are included in the same parallel region J, and others of the plurality of floating electrodes and others of the plurality of electrode fingers are included in the same non-parallel region K. This allows the plurality of floating electrodes to effectively reflect acoustic waves. Therefore, acoustic wave leakage can be effectively reduced or prevented.

The plurality of reflector electrode fingers of the reflectors 87A and 87B each have a shape in plan view that is bent at a plurality of joints, as with the electrode fingers of the IDT electrode 89. Specifically, the plurality of reflector electrode fingers extend linearly in the extended region of the parallel region J and the extended region of the non-parallel region K. The plurality of reflector electrode fingers are also bent at the boundary between the extended region of the parallel region J and the extended region of the non-parallel region K. This makes it possible to more reliably improve the resonance characteristics.

As illustrated in FIG. 31, the first envelope E81 includes a plurality of portions that are inclined with respect to the propagation axis. The first envelope E81 also includes a plurality of bent portions. More specifically, the bent portion is a portion where the extending direction of the envelope changes. In the present example embodiment, the first envelope E81 has a wavy shape in which adjacent bent portions are connected by straight lines. However, the first envelope E81 may also have a wavy shape in which adjacent bent portions are connected by curved lines.

Similarly, the second envelope E82, the third envelope E83, and the fourth envelope E84 each include a plurality of portions that are inclined with respect to the propagation axis. The second envelope E82, the third envelope E83, and the fourth envelope E84 each include a plurality of bent portions. The second envelope E82, the third envelope E83, and the fourth envelope E84 each have a wavy shape in which adjacent bent portions are connected by straight lines. However, the second envelope E82, the third envelope E83, and the fourth envelope E84 may each also have a wavy shape in which adjacent bent portions are connected by curved lines.

As described above, in the present example embodiment, the first envelope E81, the second envelope E82, the third envelope E83, and the fourth envelope E84 include the plurality of bent portions. At least one of the first envelope E81, the second envelope E82, the third envelope E83, and the fourth envelope E84 may include at least one bent portion.

An edge portion of the first busbar 83 facing the plurality of first floating electrodes 81 extends parallel or substantially parallel to the third envelope E83. Therefore, the edge portion includes a plurality of bent portions. The edge portion has a wavy shape in which adjacent bent portions are connected by straight lines.

An edge portion of the second busbar 84 facing the plurality of second floating electrodes 82 extends parallel or substantially parallel to the fourth envelope E84. Therefore, the edge portion includes a plurality of bent portions. The edge portion has a wavy shape in which adjacent bent portions are connected by straight lines.

As in the second example embodiment, mass addition films are provided in the first edge region H1, the second edge region H2, the first floating electrode formation region U1, and the second floating electrode formation region U2. Accordingly, low acoustic velocity regions are provided in the first edge region H1, the second edge region H2, the first floating electrode formation region U1, and the second floating electrode formation region U2. This makes it possible to reduce or prevent a transverse mode and effectively reduce or prevent acoustic wave energy leakage in the present example embodiment.

The multilayer structure of the piezoelectric substrate is not limited to the configuration illustrated in FIG. 2. In a ninth example embodiment of the present invention, description will be provided of an example where an acoustic wave device includes a piezoelectric substrate different from that of the first example embodiment.

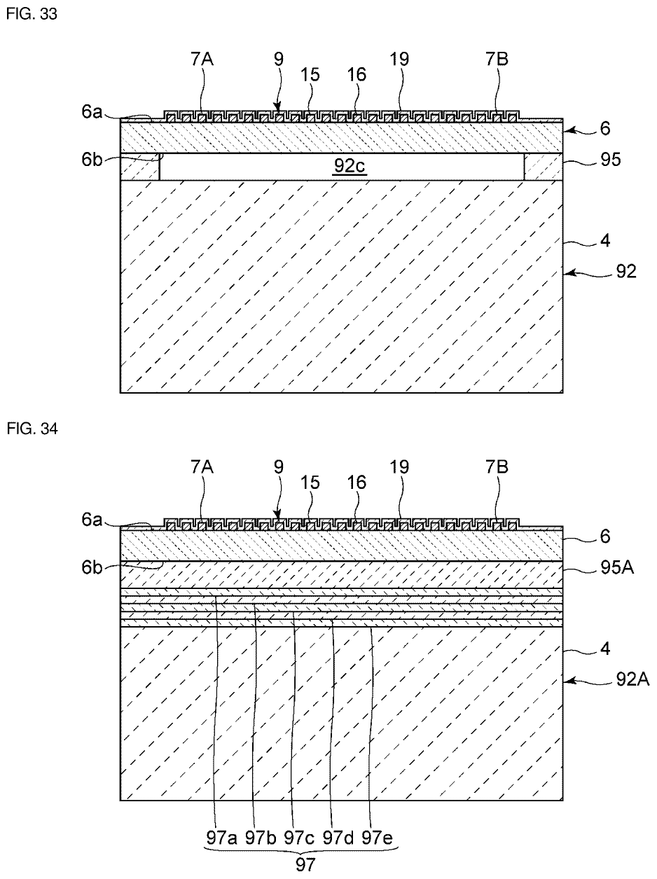

FIG. 33 is a schematic elevational cross-sectional view of an acoustic wave device according to the ninth example embodiment.

The present example embodiment differs from the first example embodiment in the multilayer structure of a piezoelectric substrate 92. Otherwise, the acoustic wave device of the present example embodiment has the same or substantially the same configuration as that of the acoustic wave device 10 of the first example embodiment.

The piezoelectric substrate 92 includes a support substrate 4, an intermediate layer 95, and a piezoelectric layer 6. The intermediate layer 95 is provided on the support substrate 4. The piezoelectric layer 6 is provided on the intermediate layer 95. In the present example embodiment, the intermediate layer 95 has a frame shape. That is, the intermediate layer 95 includes a through-hole. The support substrate 4 closes one end of the through-hole in the intermediate layer 95. The piezoelectric layer 6 closes the other end of the through-hole in the intermediate layer 95. Accordingly, a hollow portion 92c is provided in the piezoelectric substrate 92. A portion of the piezoelectric layer 6 and a portion of the support substrate 4 face each other across the hollow portion 92c.

In the present example embodiment, a main mode can be reflected toward the piezoelectric layer 6. Therefore, acoustic wave energy can be effectively confined to the piezoelectric layer 6 side. In addition, as in the first example embodiment, a transverse mode can be reduced or prevented, and acoustic wave energy leakage can be reduced or prevented.

Hereinafter, first and second modifications of the ninth example embodiment will be described, which differ from the ninth example embodiment only in the multilayer structure of the piezoelectric substrate. As in the ninth example embodiment, the transverse mode can be reduced or prevented and the acoustic wave energy leakage can be reduced or prevented in the first and second modifications.

In the first modification illustrated in FIG. 34, a piezoelectric substrate 92A includes a support substrate 4, an acoustic reflection film 97, an intermediate layer 95A, and a piezoelectric layer 6. The acoustic reflection film 97 is provided on the support substrate 4. The intermediate layer 95A is provided on the acoustic reflection film 97. The piezoelectric layer 6 is provided on the intermediate layer 95A. The intermediate layer 95A is a low acoustic velocity film.

The acoustic reflection film 97 is a multilayer body including a plurality of acoustic impedance layers. Specifically, the acoustic reflection film 97 includes a plurality of low acoustic impedance layers and a plurality of high acoustic impedance layers. The high acoustic impedance layers have a relatively high acoustic impedance. The plurality of high acoustic impedance layers of the acoustic reflection film 97 include, more specifically, a high acoustic impedance layer 97a, a high acoustic impedance layer 97c, and a high acoustic impedance layer 97e. On the other hand, the low acoustic impedance layers have a relatively low acoustic impedance. The plurality of low acoustic impedance layers of the acoustic reflection film 97 include, more specifically, a low acoustic impedance layer 97b and a low acoustic impedance layer 97d. The low acoustic impedance layers and the high acoustic impedance layers are alternately stacked. The high acoustic impedance layer 97a is the layer located closest to the piezoelectric layer 6 in the acoustic reflection film 97.

The acoustic reflection film 97 includes, for example, two low acoustic impedance layers and three high acoustic impedance layers. However, it is sufficient that the acoustic reflection film 97 includes at least one low acoustic impedance layer and one high acoustic impedance layer.

Examples of the material that can be used for the low acoustic impedance layers include silicon oxide, aluminum, or the like. Examples of the material that can be used for the high acoustic impedance layers include metal such as platinum or tungsten, and dielectrics such as aluminum nitride or silicon nitride. The material of the intermediate layer 95A may be the same as that of the low acoustic impedance layers.

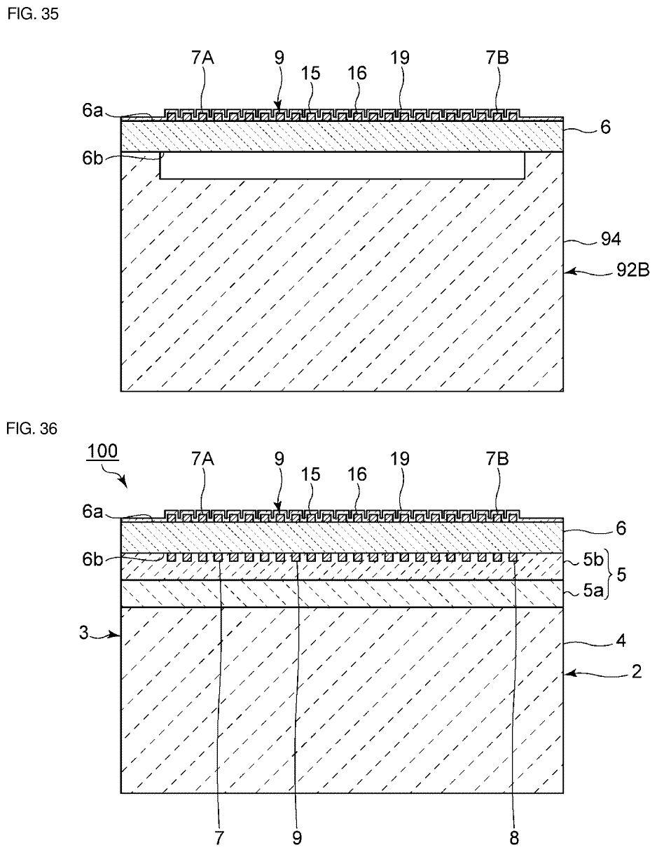

In the second modification illustrated in FIG. 35, a piezoelectric substrate 92B includes a support substrate 94 and a piezoelectric layer 6. The piezoelectric layer 6 is provided directly on the support substrate 94. More specifically, the support substrate 94 includes a recess portion. The piezoelectric layer 6 is provided on the support substrate 94 so as to close the recess portion. A hollow portion is thus provided in the piezoelectric substrate 92B. The hollow portion overlaps at least partially with the IDT electrode 9 in plan view.

FIG. 36 is a schematic elevational cross-sectional view of an acoustic wave device according to a tenth example embodiment of the present invention.

The present example embodiment differs from the first example embodiment in that IDT electrodes 9 are provided on both of a first main surface 6a and a second main surface 6b of a piezoelectric layer 6. The IDT electrode 9 provided on the second main surface 6b is embedded in a second layer 5b of an intermediate layer 5. Otherwise, an acoustic wave device 100 of the present example embodiment has the same or substantially the same configuration as that of the acoustic wave device 10 of the first example embodiment.

The IDT electrode 9 provided on the first main surface 6a of the piezoelectric layer 6 and the IDT electrode 9 provided on the second main surface 6b face each other across the piezoelectric layer 6. In the acoustic wave device 100, the IDT electrode 9 and a mass addition film are provided on the first main surface 6a in the same or substantially the same manner as in the first example embodiment. This makes it possible to reduce or prevent a transverse mode and reduce or prevent acoustic wave energy leakage.

The IDT electrodes 9 provided on the first main surface 6a and the second main surface 6b of the piezoelectric layer 6 may have different design parameters, for example.

Hereinafter, first to third modifications of the tenth example embodiment will be described, which differ from the tenth example embodiment in at least one of the configuration of electrodes provided on the second main surface of the piezoelectric layer and a multilayer structure of a piezoelectric substrate. As in the tenth example embodiment, the transverse mode can be reduced or prevented and the acoustic wave energy leakage can be reduced or prevented in the first to third modifications.

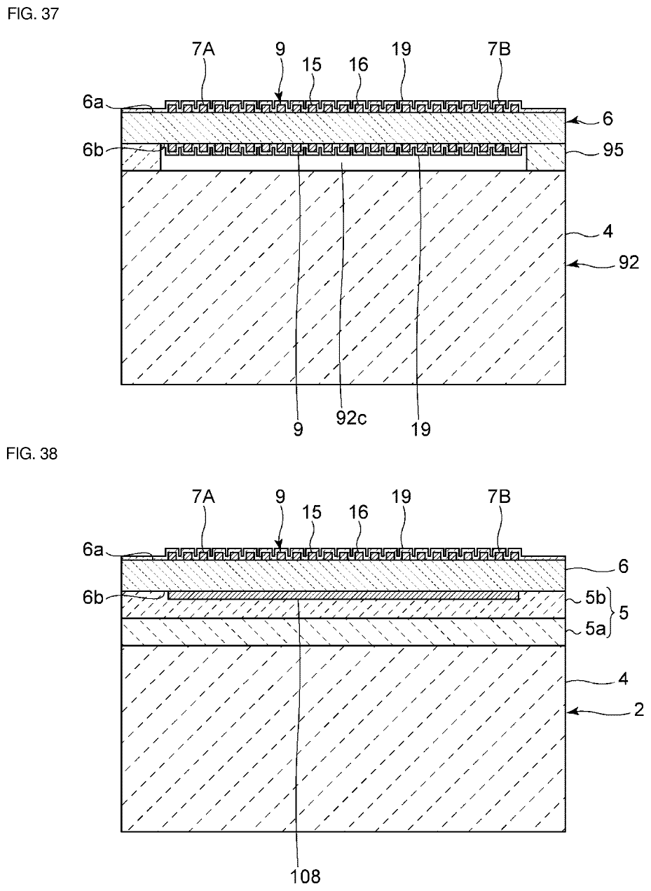

In the first modification illustrated in FIG. 37, a piezoelectric substrate 92 has the same or substantially the same configuration as in the ninth example embodiment. Specifically, the piezoelectric substrate 92 includes a support substrate 4, an intermediate layer 95, and a piezoelectric layer 6. An IDT electrode 9 provided on a second main surface 6b of the piezoelectric layer 6 is located in a hollow portion 92c. In this modification, a dielectric film 19 is provided on the second main surface 6b of the piezoelectric layer 6 so as to cover the IDT electrode 9. The material of the dielectric film 19 may be the same as or different from the material of the intermediate layer 95. However, the dielectric film 19 does not necessarily have to be provided.

In the second modification illustrated in FIG. 38, a plate-shaped electrode 108 is provided on the second main surface 6b of the piezoelectric layer 6. The IDT electrode 9 and the electrode 108 face each other across the piezoelectric layer 6. The electrode 108 is embedded in the second layer 5b.

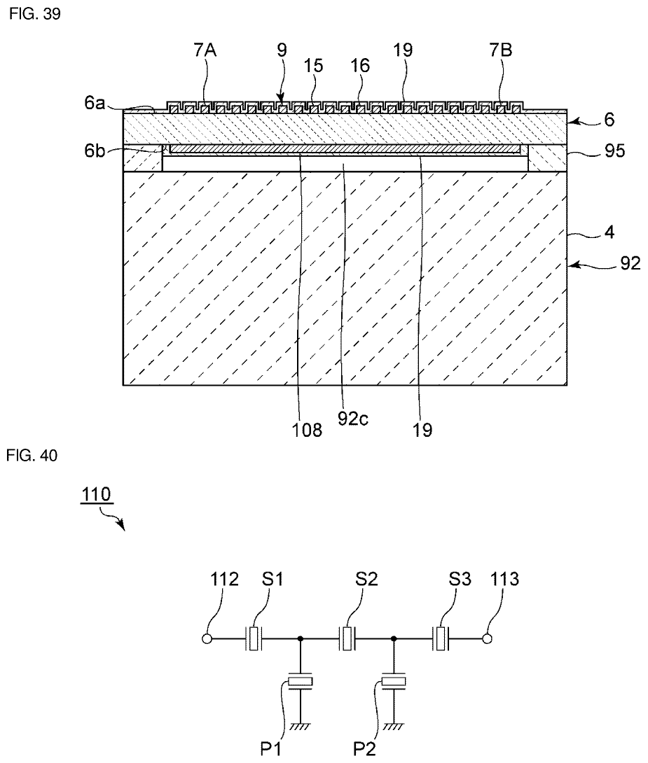

In the third modification illustrated in FIG. 39, a piezoelectric substrate 92 has the same or substantially the same configuration as in the first modification, and the same electrode 108 as in the second modification is provided on the second main surface 6b of the piezoelectric layer 6. The electrode 108 is located in the hollow portion 92c. A dielectric film 19 is provided on the second main surface 6b so as to cover the electrode 108. However, the dielectric film 19 does not necessarily have to be provided.

In the ninth and tenth example embodiments and the modifications thereof, examples have been described of the case where the IDT electrode 9 and the mass addition film have the same or substantially the same configurations as in the first example embodiment. The piezoelectric substrates of the ninth example embodiment and the respective modifications thereof can also be used when the IDT electrode and the mass addition film have configurations of example embodiments of the present invention other than those of the first example embodiment. Alternatively, the piezoelectric substrates of the ninth example embodiment and the respective modifications thereof can also be used when the electrode fingers of the IDT electrode or floating electrodes have wide portions. However, the piezoelectric substrate may include only a piezoelectric layer. The configuration of the second main surface of the piezoelectric layer, which is the same or substantially the same as that of the tenth example embodiment and the respective modifications thereof, can also be used when the IDT electrode and the mass addition film have configurations of example embodiments of the present invention other than those of the first example embodiment, or when the electrode fingers or floating electrodes include wide portions.

The acoustic wave devices according to example embodiments of the present invention can be used in filter devices, for example. This example will be described below.

FIG. 40 is a circuit diagram of a filter device according to an eleventh example embodiment of the present invention.

A filter device 110 of the present example embodiment is a ladder filter. The filter device 110 includes a first signal terminal 112, a second signal terminal 113, a plurality of serial arm resonators, and a plurality of parallel arm resonators. In the filter device 110, all of the serial arm resonators and all of the parallel arm resonators are acoustic wave resonators. Furthermore, all of the serial arm resonators and all of the parallel arm resonators are acoustic wave devices according to example embodiments of the present invention. However, it is sufficient that at least one of the plurality of acoustic wave resonators in the filter device 110 is an acoustic wave device according to an example embodiment of the present invention.

The first signal terminal 112 is an antenna terminal. The antenna terminal is connected to an antenna. However, the first signal terminal 112 does not necessarily have to be the antenna terminal. The first signal terminal 112 and the second signal terminal 113 may be configured, for example, as electrode pads or wiring.

The plurality of serial arm resonators of the present example embodiment include, specifically, serial arm resonators S1, S2, and S3. The plurality of serial arm resonators are connected in series between the first signal terminal 112 and the second signal terminal 113. The plurality of parallel arm resonators include, specifically, parallel arm resonators P1 and P2. The parallel arm resonator P1 is connected between a connection point between the serial arm resonators S1 and S2 and a ground potential. The parallel arm resonator P2 is connected between a connection point between the serial arm resonators S2 and S3 and the ground potential. The circuit configuration of the filter device 110 is not limited to the above. The filter device 110 may include a longitudinally coupled resonator acoustic wave filter, for example.

The acoustic wave resonators in the filter device 110 are the acoustic wave devices according to example embodiments of the present invention. Therefore, a transverse mode can be reduced or prevented, and acoustic wave energy leakage can be reduced or prevented in the acoustic wave resonators of the filter device 110.

Hereinafter, description will be provided of an example of procedures to observe the shapes of electrode fingers of an IDT electrode or reflector electrode fingers of a reflector.

First, an image including an electrode finger or reflector electrode finger is obtained using a microscope or the like. For example, a scanning electron microscope (SEM), an optical microscope, or a laser scanning microscope may be used.

Next, the image is processed so that end portions of the electrode finger can be determined by adjusting the contrast or the like. Next, the end portion of the electrode finger is detected to extract coordinate values of the end portion. Then, the contour of the extracted end portion of the electrode finger is interpolated by a polynomial approximated curve within an appropriate region size.

Next, the center of gravity is determined from the curves at both end edges of the electrode finger. The center of gravity here is a linear center of gravity. Specifically, first, any adjacent points on the curves at both edges are connected by a straight line. Similarly, a plurality of pairs of points are connected by a plurality of straight lines. A line connecting the midpoints of these straight lines is considered as the center of gravity.

A curve obtained by polynomial approximation of the linear center of gravity in a local region is the curve representing the center of gravity. A normal direction at each coordinate point on the center of gravity is calculated from the equation of this curve. Then, based on the normal direction, the width of the electrode finger, electrode finger pitch, and duty ratio are calculated. The width of the electrode finger is the dimension of the electrode finger in the normal direction. The electrode finger pitch is the center-to-center distance between adjacent electrode fingers in the normal direction. The duty ratio is the value obtained by dividing the width of the electrode finger by the electrode finger pitch.

As described above, the curvature represents the degree of bending of a curve or curved surface. The radius of a locally approximated arc at any point on a curve can be calculated, and the reciprocal of that radius can be expressed as the curvature. That is, the curvature is 1/r, where r is the calculated radius.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
an IDT electrode on the piezoelectric layer, and including a pair of busbars, a plurality of electrode fingers, and a plurality of first floating electrodes not connected to the pair of busbars or the plurality of electrode fingers; wherein
the pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other;
a region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side;
the plurality of first floating electrodes are located between the first edge region and the first busbar, and a region where the plurality of first floating electrodes are provided a first floating electrode formation region; and
the acoustic wave device further includes:
a first mass addition film in the first edge region; and
a second mass addition film in the first floating electrode formation region.

2. An acoustic wave device comprising:
a piezoelectric substrate including a piezoelectric layer; and
an IDT electrode on the piezoelectric layer, and including a pair of busbars, a plurality of electrode fingers, and a plurality of first floating electrodes not connected to the pair of busbars or the plurality of electrode fingers; wherein
the pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other;
a region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side;
the plurality of first floating electrodes are located between the first edge region and the first busbar, and a region where the plurality of first floating electrodes are located is a first floating electrode formation region;
in the first edge region, at least one of the plurality of first electrode fingers or the plurality of second electrode fingers include first wide portions wider than a width in the central region; and
in the first floating electrode formation region, the acoustic wave device includes at least one of a configuration in which the plurality of first electrode fingers include second wide portions wider than the width in the central region, or a configuration in which the plurality of first floating electrodes include second wide portions wider than other portions.

3. An acoustic wave device comprising:
a piezoelectric substrate including a piezoelectric layer; and
an IDT electrode on the piezoelectric layer, and including a pair of busbars, a plurality of electrode fingers, and a plurality of first floating electrodes not connected to the pair of busbars or the plurality of electrode fingers; wherein
the pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other;
a region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side;
the plurality of first floating electrodes are located between the first edge region and the first busbar, and a region where the plurality of first floating electrodes are located is a first floating electrode formation region; and
the acoustic wave device further includes:
a first mass addition film in the first edge region; wherein
in the first floating electrode formation region, the acoustic wave device has at least one of a configuration in which the plurality of first electrode fingers include second wide portions wider than a width in the central region, or a configuration in which the plurality of first floating electrodes include second wide portions wider than other portions.

4. An acoustic wave device comprising:
a piezoelectric substrate including a piezoelectric layer; and
an IDT electrode on the piezoelectric layer, and including a pair of busbars, a plurality of electrode fingers, and a plurality of first floating electrodes not connected to the pair of busbars or the plurality of electrode fingers; wherein
the pair of busbars include a first busbar and a second busbar facing each other, the plurality of electrode fingers include a plurality of first electrode fingers and a plurality of second electrode fingers, the plurality of first electrode fingers each include one end portion connected to the first busbar, the plurality of second electrode fingers each include one end portion connected to the second busbar, and the plurality of first electrode fingers and the plurality of second electrode fingers are interdigitated with each other;
a region where the plurality of first electrode fingers and the plurality of second electrode fingers that are adjacent to each other overlap with each other in an acoustic wave propagation direction is an intersection region, the intersection region includes a central region located on a center side in a propagation orthogonal direction that is orthogonal or substantially orthogonal to the acoustic wave propagation direction, and a first edge region and a second edge region facing each other across the central region, the first edge region is located on the first busbar side, and the second edge region is located on the second busbar side;
the plurality of first floating electrodes are located between the first edge region and the first busbar, and a region where the plurality of first floating electrodes are provided is a first floating electrode formation region;
in the first edge region, at least one of the plurality of first electrode fingers or the plurality of second electrode fingers include first wide portions wider than a width in the central region; and
the acoustic wave device further includes:
a second mass addition film in the first floating electrode formation region.

5. The acoustic wave device according to claim 1, further comprising a third mass addition film in the second edge region.

6. The acoustic wave device according to claim 1, wherein, in the second edge region, at least one of the plurality of first electrode fingers or the plurality of second electrode fingers include third wide portions wider than a width in the central region.

7. The acoustic wave device according to claim 1, wherein
the IDT electrode further includes a plurality of second floating electrodes not connected to the first busbar, the second busbar, the plurality of first electrode fingers, or the plurality of second electrode fingers, and located between the second edge region and the second busbar;
a region where the plurality of second floating electrodes are provided is a second floating electrode formation region; and
the acoustic wave device further includes:
a fourth mass addition film in the second floating electrode formation region.

8. The acoustic wave device according to claim 1, wherein
the IDT electrode further includes a plurality of second floating electrodes not connected to the first busbar, the second busbar, the plurality of first electrode fingers, or the plurality of second electrode fingers, and located between the second edge region and the second busbar;
a region where the plurality of second floating electrodes are provided is a second floating electrode formation region; and
in the second floating electrode formation region, the acoustic wave device has at least one of a configuration in which the plurality of second electrode fingers include fourth wide portions wider than a width in the central region, and a configuration in which the plurality of second floating electrodes include fourth wide portions wider than other portions.

9. The acoustic wave device according to claim 1, wherein, when a virtual line connecting tip ends of the plurality of second electrode fingers is a first envelope, an extending direction of the first envelope intersects with, but is not orthogonal to, an extending direction of the plurality of first electrode fingers and the plurality of second electrode fingers.

10. The acoustic wave device according to claim 9, wherein the extending direction of the first envelope intersects with, but is not orthogonal to, an extending direction of the plurality of first floating electrodes.

11. The acoustic wave device according to claim 1, wherein shapes of the plurality of first electrode fingers and the plurality of second electrode fingers in plan view include a curved shape.

12. The acoustic wave device according to claim 11, wherein the shapes of the plurality of first electrode fingers and the plurality of second electrode fingers in plan view include an arc shape or an elliptical arc shape.

13. The acoustic wave device according to claim 11, wherein, when a virtual line connecting tip ends of the plurality of second electrode fingers is a first envelope and a virtual line connecting tip ends of the plurality of first electrode fingers is a second envelope, a portion of each of the plurality of first electrode fingers that includes a portion located on the first envelope and is adjacent to a tip end portion of any of the second electrode fingers is an adjacent portion of the first electrode finger, and a portion of each of the plurality of second electrode fingers that includes a portion located on the second envelope and is adjacent to a tip end portion of any of the plurality of first electrode fingers is an adjacent portion of the second electrode finger, a curvature of each of the first electrode fingers and the second electrode fingers is not constant in the intersection region, and the curvature differs between the tip end portions located on the first envelope side, between the adjacent portions, or between the tip end portion and the adjacent portion in at least one pair of electrode fingers among the plurality of first electrode fingers and the plurality of second electrode fingers.

14. The acoustic wave device according to claim 11, wherein
when a region where the shapes of the plurality of first electrode fingers and the plurality of second electrode fingers in plan view are curved shapes is a curved region, the intersection region includes at least one of the curved region;
when a virtual line connecting tip ends of the plurality of second electrode fingers is a first envelope, a virtual line connecting tip ends of the plurality of first electrode fingers is a second envelope, and a virtual line extending parallel or substantially parallel to the first envelope or the second envelope and passing through the central region in the intersection region is an intersection line, the intersection line is an edge portion of the curved region;
a portion of each of the plurality of first electrode fingers that intersects with the intersection line is a first intersection portion, and a portion of each of the second electrode fingers that intersects with the intersection line is a second intersection portion; and
a curvature of each of the plurality of first electrode fingers and the plurality of second electrode fingers in the curved region is not constant, and the curvature differs between the first intersection portion and the second intersection portion in at least one pair of electrode fingers among the plurality of first electrode fingers and the plurality of second electrode fingers.

15. The acoustic wave device according to claim 11, wherein the plurality of first floating electrodes have a curved shape in plan view.

16. The acoustic wave device according to claim 11, wherein resonant frequencies or anti-resonant frequencies of a main mode match or substantially match in the intersection region.

17. The acoustic wave device according to claim 16, wherein
the piezoelectric layer includes a propagation axis;
an excitation direction of an acoustic wave at any portion of any of the plurality of first electrode fingers and the plurality of second electrode fingers in the intersection region is one of first, second, and third directions, the first direction being perpendicular or substantially perpendicular to an extending direction of the any of the plurality of first electrode fingers and the plurality of second electrode fingers, the second direction being a direction in which a distance between the any of the plurality of first electrode fingers and the plurality of second electrode fingers and one of the plurality of first electrode finger or the plurality of second electrode finger adjacent to the any of the plurality of first electrode fingers and the plurality of second electrode fingers is shortest, the third direction being a direction of an electric field vector generated between the any of the plurality of first electrode fingers and the plurality of second electrode fingers and the one of the plurality of first electrode finger or the plurality of second electrode finger adjacent to the electrode finger; and
when an angle between the excitation direction and an extending direction of the propagation axis is an excitation angle, at least one of a duty ratio, an electrode finger pitch, and a thickness of the plurality of first electrode fingers and the plurality of second electrode fingers is constant in a portion of the IDT electrode where the excitation angle is the same.

18. The acoustic wave device according to claim 17, wherein
the duty ratio is constant in the portion of the IDT electrode where the excitation angle is the same; and
the duty ratio in the portion of the IDT electrode where the excitation angle is the same increases or decreases as an absolute value of the excitation angle increases, so that the resonant frequencies or anti-resonant frequencies of the main mode match or substantially match in at least a portion of the intersection region.

19. The acoustic wave device according to claim 17, wherein
the electrode finger pitch is constant in the portion of the IDT electrode where the excitation angle is the same; and
the electrode finger pitch in the portion of the IDT electrode where the excitation angle is the same increases or decreases as an absolute value of the excitation angle increases, so that the resonant frequencies or anti-resonant frequencies of the main mode match or substantially match in at least a portion of the intersection region.

20. The acoustic wave device according to claim 17, wherein
the thickness of the plurality of first electrode fingers and the plurality of second electrode fingers is constant in the portion of the IDT electrode where the excitation angle is the same; and
the thickness of the plurality of first electrode fingers and the plurality of second electrode fingers in the portion where the excitation angle is the same increases or decreases as an absolute value of the excitation angle increases, so that the resonant frequencies or anti-resonant frequencies of the main mode match or substantially match in at least a portion of the intersection region.

21. The acoustic wave device according to claim 1, wherein
at least the first busbar of the pair of busbars includes an inner busbar portion and an outer busbar portion facing each other and a plurality of connection portions connecting the inner busbar portion and the outer busbar portion;
the inner busbar portion is located on the second busbar side; and
the first busbar includes a plurality of apertures surrounded by the inner busbar portion, the outer busbar portion, and the plurality of connection portions.

22. The acoustic wave device according to claim 1, wherein, when a wavelength defined by an electrode finger pitch is λ and a virtual line connecting tip ends of the plurality of floating electrodes on the first busbar side is a third envelope, a dimension of a region between the third envelope and the first busbar in a direction normal to the third envelope is greater than or equal to about 1λ.

23. The acoustic wave device according to claim 1, wherein
the piezoelectric substrate includes a support substrate; and
the piezoelectric layer is on the support substrate.

24. The acoustic wave device according to claim 23, wherein the piezoelectric substrate includes an intermediate layer between the support substrate and the piezoelectric layer.

25. The acoustic wave device according to claim 23, wherein the piezoelectric substrate includes a hollow portion, and a portion of the support substrate and a portion of the piezoelectric layer face other across the hollow portion.

26. The acoustic wave device according to claim 1, wherein the piezoelectric substrate includes only the piezoelectric layer.

27. A filter device comprising:
a plurality of acoustic wave resonators, wherein
at least one of the acoustic wave resonators includes the acoustic wave device according to claim 1.
